(19) United States
(12) Patent Application Publication
(10) Pub. No.: US 2011/0014569 A1
(43) Pub. Date: Jan. 20, 2011

(54) RADIATION-SENSITIVE RESIN COMPOSITION AND POLYMER

(75) Inventors: Kazuki KASAHARA, Tokyo (JP); Hirokazu SAKAKIBARA, Tokyo (JP); Takehiko NARUOKA, Tokyo (JP)

Correspondence Address: Ditthavong Mori & Steiner, P.C., 918 Prince Street, Alexandria, VA, 22314, US

(73) Assignee: JSR Corporation, Tokyo (JP)

(21) Appl. No.: 12/836,565

(22) Filed: Jul. 14, 2010

(30) Foreign Application Priority Data
Jul. 15, 2009 (JP) 2009-167220

(51) Int. Cl. G03F 7/004; C08F 24/00

(52) U.S. Cl. 430/270.1; 526/268

(57) ABSTRACT

A radiation-sensitive resin composition includes a solvent and a polymer. The polymer includes a first repeating unit shown by a general formula (1) in which R¹ represents a hydrogen atom, a methyl group, or a trifluoromethyl group, and Z represents a monovalent group that generates an acid upon exposure to radiation.

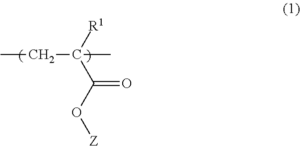

### CROSS-REFERENCE TO RELATED APPLICATIONS

The present application claims priority under 35 U.S.C. §119 to Japanese Patent Application No. 2009-167220, filed July 15, 2009. The contents of this application are incorporated herein by reference in their entirety.

### BACKGROUND OF THE INVENTION

1. Field of the Invention

The present invention relates to a radiation-sensitive resin composition and a polymer.

2. Discussion of the Background

A chemically-amplified radiation-sensitive resin composition generates an acid upon exposure to deep ultraviolet rays having a wavelength of 250 nm or less (e.g., KrF excimer laser light or ArF excimer laser light) or electron beams. A difference in dissolution rate in a developer occurs between the exposed area and the unexposed area due to chemical reactions catalyzed by the acid, so that a resist pattern is formed on a substrate.

For example, when using a KrF excimer laser (wavelength: 248 nm) as a light source, a chemically-amplified radiation-sensitive resin composition that includes a polymer having a poly(hydroxystyrene) (PHS) basic skeleton that has a low absorbance at 248 nm has been used. An excellent pattern can be formed with high sensitivity and high resolution by utilizing such a composition.

However, when using a light source having a shorter wavelength (e.g., ArF excimer laser (wavelength: 193 nm)) in order to implement advanced microfabrication, it is difficult to utilize an aromatic compound (e.g., PHS) that has a high absorbance at 193 nm.

Therefore, a resin composition that includes a polymer including an alicyclic hydrocarbon that does not have a high absorbance at 193 nm in its skeleton (particularly a polymer including a lactone skeleton in its repeating unit) has been used as a lithography material when using an ArF excimer laser as a light source.

For example, a radiation-sensitive resin composition that includes a polymer including a mevalonic lactone skeleton or a γ-butyrolactone skeleton in its repeating unit has been disclosed (see Japanese Patent Application Publication (KOKAI) No. 9-73173 and U.S. Pat. No. 6,388,101). A resin composition that includes a polymer including an alicyclic lactone skeleton in its repeating unit has also been disclosed (see Japanese Patent Application Publications (KOKAI) No. 2000-159758, No. 2001-109154, No. 2004-101642, No. 2003-113174, No. 2003-147023, No. 2002-308866, No. 2002-371114, No. 2003-64134, No. 2003-270787, No. 2000-26446, and No. 2000-122294).

### SUMMARY OF THE INVENTION

According to one aspect of the present invention, a radiation-sensitive resin composition includes a solvent and a polymer. The polymer includes a first repeating unit shown by a general formula (1) and at least one of a second repeating unit shown by a general formula (2), a third repeating unit shown by a general formula (3), and a fourth repeating unit shown by a general formula (4),

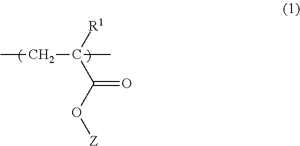

wherein R¹ represents a hydrogen atom, a methyl group, or a trifluoromethyl group, and Z represents a monovalent group that generates an acid upon exposure to radiation,

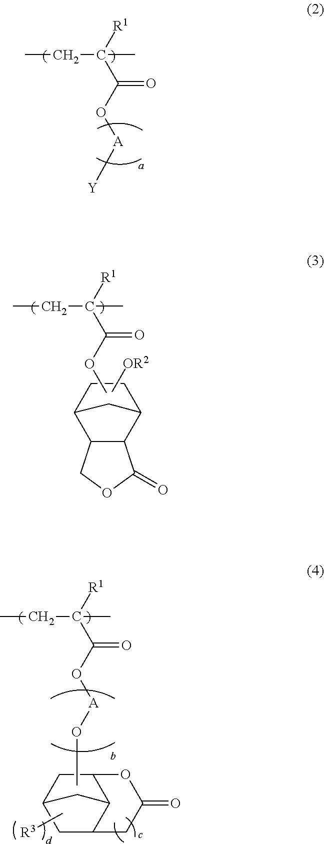

wherein R¹ represents a hydrogen atom, a methyl group, or a trifluoromethyl group, A represents a methylene group, a linear or branched alkylene group having 2 to 10 carbon atoms, or an arylene group having 3 to 10 carbon atoms, Y represents a group that includes a structure shown by a following general formula (i), a is 0 or 1, R² represents a linear or branched alkyl group having 1 to 10 carbon atoms, R³ represents a linear or branched alkyl group having 1 to 10 carbon atoms, a halogen atom, or a cyano group, b is an integer from 2 to 4, c is 0 or 1, and d is an integer from 0 to 2,

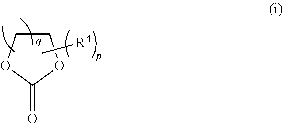

wherein R⁴ represents a hydrogen atom or a linear or branched alkyl group having 1 to 5 carbon atoms, p is 1 or 2, and q is 1 or 2, and two R⁴ is same or different when p is 2.

According to another aspect of the present invention, a polymer includes a first repeating unit (1) shown by a following general formula (1) and at least one of a second repeating unit shown by a following general formula (2), a third repeating unit shown by a following general formula (3), and a fourth repeating unit shown by a following general formula (4),

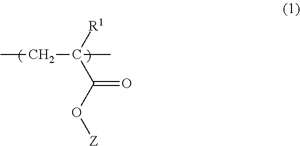

wherein R¹ represents a hydrogen atom, a methyl group, or a trifluoromethyl group, and Z represents a monovalent group that generates an acid upon exposure to radiation,

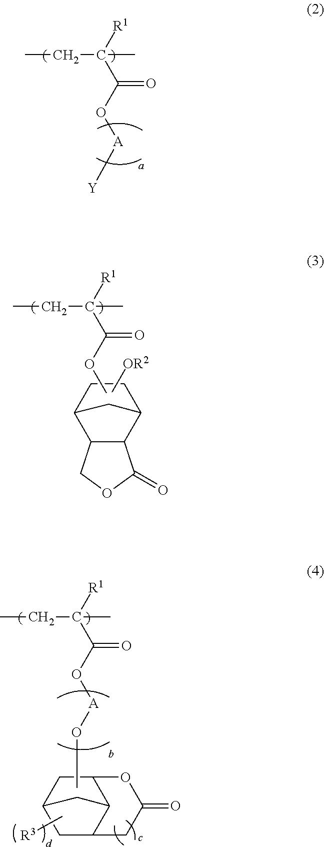

wherein R¹ represents a hydrogen atom, a methyl group, or a trifluoromethyl group, A represents a methylene group, a linear or branched alkylene group having 2 to 10 carbon atoms, or an arylene group having 3 to 10 carbon atoms, Y represents a group that includes a structure shown by a following general formula (i), a is 0 or 1, R² represents a linear or branched alkyl group having 1 to 10 carbon atoms, R³ represents a linear or branched alkyl group having 1 to 10 carbon atoms, a halogen atom, or a cyano group, b is an integer from 2 to 4, c is 0 or 1, and d is an integer from 0 to 2,

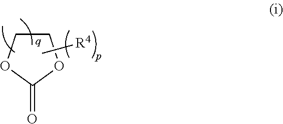

wherein R⁴ represents a hydrogen atom or a linear or branched alkyl group having 1 to 5 carbon atoms, p is 1 or 2, and q is 1 or 2, wherein two R⁴ is same or different when p is 2.

### DESCRIPTION OF THE EMBODIMENTS

Embodiments of the invention are described below. Note that the invention is not limited to the following embodiments. Various modifications and improvements may be made of the following embodiments without departing from the scope of the invention based on the knowledge of a person having ordinary skill in the art.

The term “group” used herein refers to a substituted or unsubstituted group. The term “group” used herein refers to a linear or branched group. For example, the term “alkyl group” used herein includes an unsubstituted linear alkyl group, a linear group in which at least one hydrogen atom is substituted with another functional group, a branched group in which at least one hydrogen atom is substituted with another functional group, and an unsubstituted branched alkyl group. The term “(meth)acrylic acid” used herein refers to acrylic acid and methacrylic acid.

### <Radiation-Sensitive Resin Composition>

A radiation-sensitive resin composition according to one embodiment of the invention includes (A) a polymer and (B) a solvent, the polymer (A) including a repeating unit (1) and at least one repeating unit selected from the group consisting of a repeating unit (2), a repeating unit (3), and a repeating unit (4). The details of the radiation-sensitive resin composition are described below.

### A. Polymer (A)

The polymer (A) includes the repeating unit (1) and at least one repeating unit selected from the group consisting of the repeating unit (2), the repeating unit (3), and the repeating unit (4).

### A-1. Repeating Unit (1)

The repeating unit (1) included in the polymer (A) is shown by the following general formula (1), and includes a photoacid-generating group that generates an acid upon exposure to radiation.

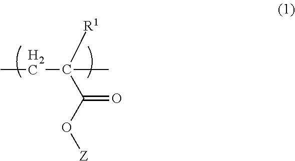

wherein R¹ represents a hydrogen atom, a methyl group, or a trifluoromethyl group, and Z represents a monovalent group that generates an acid upon exposure to radiation.

The repeating unit (1) is preferably the following repeating unit (1-1) or (1-2).

### A-1-1. Repeating Unit (1-1)

The repeating unit (1-1) preferably has a structure shown by the following general formula (1-1).

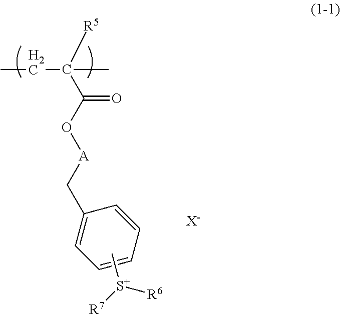

wherein R⁵ represents a hydrogen atom, a methyl group, or a trifluoromethyl group, R⁶ and R⁷ represent a substituted or unsubstituted linear or branched alkyl group having 1 to 10 carbon atoms, a substituted or unsubstituted linear or branched alkoxy group having 1 to 10 carbon atoms, or a substituted or unsubstituted aryl group having 3 to 10 carbon atoms, A represents a methylene group, a linear or branched alkylene group having 2 to 10 carbon atoms, or an arylene group having 3 to 10 carbon atoms, and X represents a counter anion of the sulfonium ion.

Specific examples of the substituted or unsubstituted linear or branched alkyl group having 1 to 10 carbon atoms represented by R⁶ and R⁷ (monovalent organic groups) in the general formula (1-1) include a methyl group, an ethyl group, an n-propyl group, an i-propyl group, an n-butyl group, a 2-methylpropyl group, a 1-methylpropyl group, a t-butyl group, an n-pentyl group, an n-hexyl group, a hydroxymethyl group, a hydroxyethyl group, a trifluoromethyl group, and the like. At least one hydrogen atom of these alkyl groups may be substituted with a halogen atom or the like.

Specific examples of the substituted or unsubstituted linear or branched alkoxy group having 1 to 10 carbon atoms represented by R⁶ and R⁷ (monovalent organic groups) in the general formula (1-1) include a methoxy group, an ethoxy group, an n-propoxy group, an i-propoxy group, an n-butoxy group, a 2-methylpropoxy group, a 1-methylpropoxy group, a t-butoxy group, an n-pentyloxy group, a neopentyloxy group, an n-hexyloxy group, an n-heptyloxy group, an n-octyloxy group, a 2-ethylhexyloxy group, an n-nonyloxy group, an n-decyloxy group, and the like. At least one hydrogen atom of these alkoxy groups may be substituted with a halogen atom or the like.

Specific examples of the substituted or unsubstituted aryl group having 3 to 10 carbon atoms represented by R⁶ and R⁷ (monovalent organic groups) in the general formula (1-1) include a phenyl group, a naphthyl group, and the like. At least one hydrogen atom of these aryl groups may be substituted with a halogen atom or the like.

Among these alkyl groups, alkoxy groups, and aryl groups, a phenyl group or a naphthyl group is preferable as R⁶ and R⁷ in the general formula (1-1) in order to obtain a compound that exhibits excellent stability.

Specific examples of the linear or branched alkylene group having 2 to 10 carbon atoms represented by A (divalent organic group) in the general formula (1-1) include an ethylene group, a 1,3-propylene group, a 1,2-propylene group, a butylene group, a pentamethylene group, a hexamethylene group, a heptamethylene group, an octamethylene group, a nonamethylene group, a decamethylene group, a 1-methyl-1,3-propylene group, a 2-methyl-1,3-propylene group, a 2-methyl-1,2-propylene group, a 1-methyl-1,4-butylene group, a 2-methyl-1,4-butylene group, and the like.

Specific examples of the arylene group having 3 to 10 carbon atoms represented by A (divalent organic group) in the general formula (1-1) include a phenylene group, a naphthylene group, an anthrylene group, a phenanthrylene group, and the like.

A (divalent organic group) in the general formula (1-1) is preferably a methylene group or a linear or branched alkylene group having 2 to 10 carbon atoms, and particularly preferably an ethylene group or a propylene group in order to obtain a compound that exhibits excellent stability.

Examples of the counter anion represented by X⁻ in the general formula (1-1) include a sulfonate anion, a carboxylate anion, a halogen anion, a BF⁴⁻ ion, a PF⁶⁻ ion, a tetraarylboronium anion, and the like.

The sulfonate anion or the carboxylate anion that may be used as the counter anion represented by X⁻ in the general formula (1-1) preferably include an alkyl group, an aryl group, an aralkyl group, an alicyclic alkyl group, a halogen-substituted alkyl group, a halogen-substituted aryl group, a halogen-substituted aralkyl group, an oxygen-substituted alicyclic alkyl group, a halogen-substituted alicyclic hydrocarbon group, or the like. A fluorine atom is preferable as the halogen substituent.

Specific examples of the halogen anion that may be used as the counter anion represented by X⁻ in the general formula (1-1) include a chloride anion, a bromide anion, and the like. Specific examples of the tetraaryl borate anion include a tetraphenyl borate anion, a B[C₆H₄(CF₃)₂]⁴⁻ ion, and the like.

A monomer that produces the repeating unit (1-1) preferably has a structure shown by the following general formula (1-1-1).

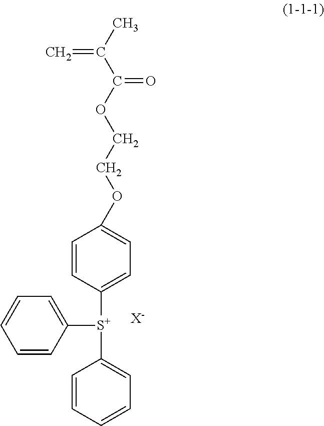

Specific examples of the counter anion represented by X⁻ in the general formula (1-1-1) include anions shown by the following formulas (1a-1) to (1a-26), and the like.

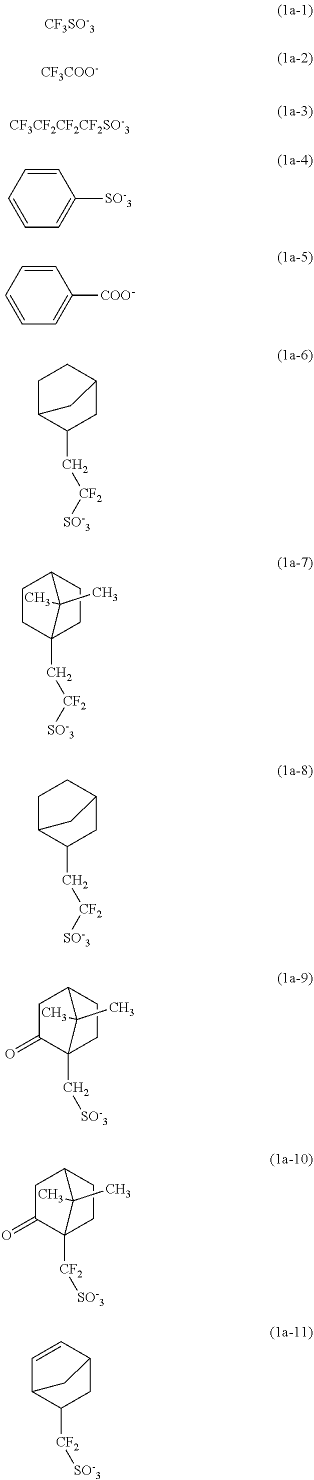

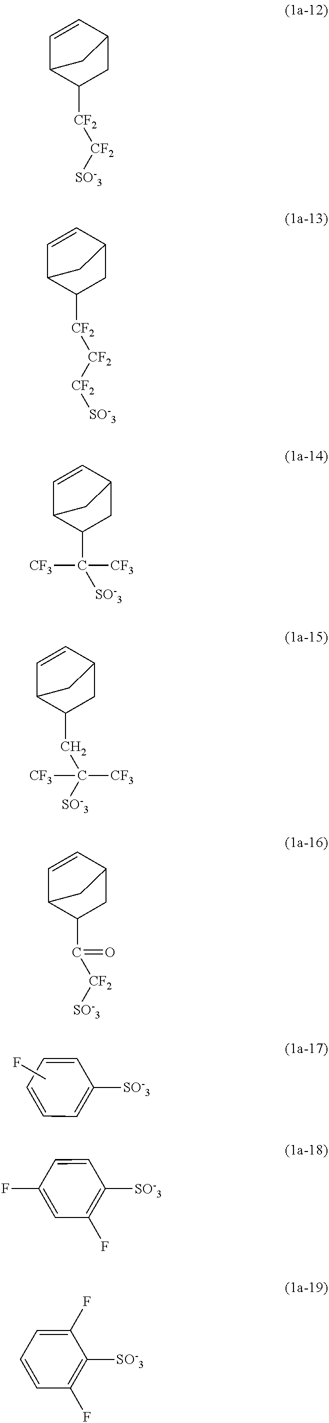

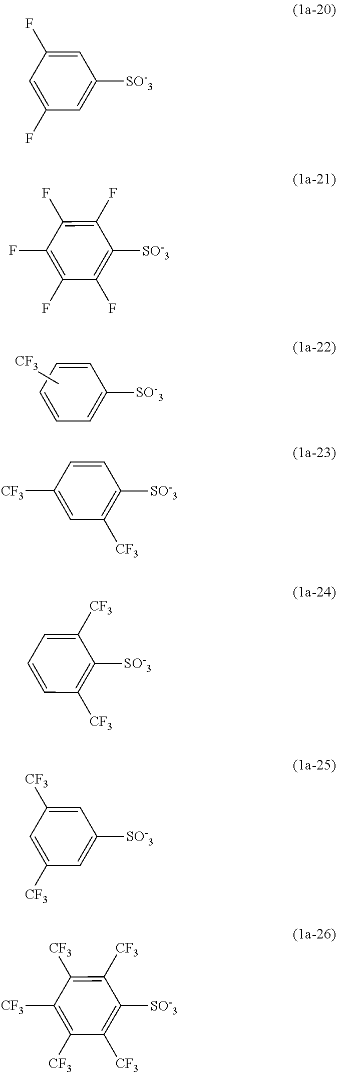

### A-1-2. Repeating Unit (1-2)

The repeating unit (1-2) preferably has a structure shown by the following general formula (1-2).

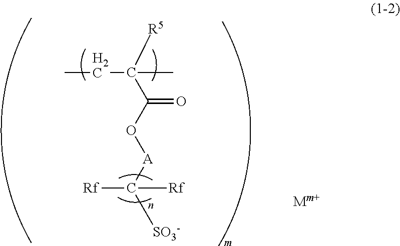

wherein R⁸ represents a hydrogen atom, a methyl group, or a trifluoromethyl group, Rf represent a fluorine atom or a linear or branched perfluoroalkyl group having 1 to 10 carbon atoms, A represents a methylene group, a linear or branched alkylene group having 2 to 10 carbon atoms, or an arylene group having 3 to 10 carbon atoms, M^{m+} represents an onium cation, m is an integer from 1 to 3, and n is an integer from 1 to 8.

Specific examples of the linear or branched perfluoroalkyl group having 1 to 10 carbon atoms represented by Rf in the general formula (1-2) include linear perfluoroalkyl groups such as a trifluoromethyl group, a pentafluoroethyl group, a heptafluoropropyl group, a nonafluorobutyl group, an undecafluoropentyl group, a tridecafluorohexyl group, a pentadecafluoroheptyl group, a heptadecafluorooctyl group, a nonadecafluorononyl group, and a heneicosafluorodecyl group; branched perfluoroalkyl groups such as a (1-trifluoromethyl)tetrafluoroethyl group, a (1-trifluoromethyl)hexafluoropropyl group, and a 1,1-bistrifluoromethyl-2,2,2-trifluoroethyl group; and the like.

A fluorine atom, a trifluoromethyl group, or the like is preferable as Rf in the general formula (1-2) in order to obtain excellent resolution. Note that the two Rf in the general formula (1-2) may be the same or different.

n in the general formula (1-2) is an integer from 1 to 8, and preferably 1 or 2.

Preferable examples of the linear or branched alkylene group having 2 to 10 carbon atoms represented by A in the general formula (1-2) include an ethylene group, a 1,3-propylene group, a 1,2-propylene group, a butylene group, a pentamethylene group, a hexamethylene group, a heptamethylene group, an octamethylene group, a nonamethylene group, a decamethylene group, a 1-methyl-1,3-propylene group, a 2-methyl-1,3-propylene group, a 2-methyl-1,2-propylene group, a 1-methyl-1,4-butylene group, a 2-methyl-1,4-butylene group, a methylidyne group, an ethylidene group, a propylidene group, a 2-propylidene group, and the like.

Preferable examples of the arylene group having 3 to 10 carbon atoms represented by A in the general formula (1-2) include a phenylene group, a naphthylene group, an anthrylene group, a phenanthrylene group, and the like.

A methylene group or a linear or branched alkylene group having 2 to 10 carbon atoms is preferable as the divalent organic group represented by A.

Specific examples of the onium cation represented by M^{m+} in the general formula (1-2) include a sulfonium cation, an iodonium cation, a phosphonium cation, a diazonium cation, an ammonium cation, a pyridinium cation, and the like. Among these, a sulfonium cation shown by the following general formula (2a) and an iodonium cation shown by the following general formula (2b) are preferable.

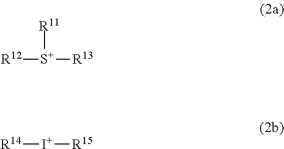

R¹¹, R¹², and R¹³ in the general formula (2a) represent a substituted or unsubstituted alkyl group having 1 to 10 carbon atoms or a substituted or unsubstituted aryl group having 4 to 18 carbon atoms, and at least two of R¹¹, R¹², and R¹³ may bond to form a cyclic group that includes the sulfonium cation.

R¹⁴ and R¹⁵ in the general formula (2b) represent a substituted or unsubstituted alkyl group having 1 to 10 carbon atoms or a substituted or unsubstituted aryl group having 4 to 18 carbon atoms, or bond to form a cyclic group that includes the iodonium cation.

Specific examples of the unsubstituted alkyl group having 1 to 10 carbon atoms represented by R¹¹ to R¹⁵ in the general formulas (2a) and (2b) include linear or branched alkyl groups such as a methyl group, an ethyl group, an n-propyl group, an i-propyl group, an n-butyl group, a 1-methylpropyl group, a 2-methylpropyl group, a t-butyl group, an n-pentyl group, an i-pentyl group, a 1,1-dimethylpropyl group, a 1-methylbutyl group, an n-hexyl group, an i-hexyl group, a 1,1-dimethylbutyl group, an n-heptyl group, an n-octyl group, an i-octyl group, a 2-ethylhexyl group, an n-nonyl group, and an n-decyl group.

Examples of the substituted alkyl group having 1 to 10 carbon atoms represented by R¹¹ to R¹⁵ in the general formulas (2a) and (2b) include a group obtained by substituting at least one hydrogen atom of the unsubstituted alkyl group with an aryl group; a linear, branched, or cyclic alkenyl group; a group that includes a heteroatom (e.g., halogen atom, oxygen atom, nitrogen atom, sulfur atom, phosphorus atom, or silicon atom); or the like. Specific examples of such a group include a benzyl group, a methoxymethyl group, a methylthiomethyl group, an ethoxymethyl group, an ethylthiomethyl group, a phenoxymethyl group, a methoxycarbonylmethyl group, an ethoxycarbonylmethyl group, an acetylmethyl group, a fluoromethyl group, a trifluoromethyl group, a chloromethyl group, a trichloromethyl group, a 2-fluoropropyl group, a (trifluoroacetyl)methyl group, a (trichloroacetyl)methyl group, a (pentafluorobenzoyl)methyl group, an aminomethyl group, a (cyclohexylamino)methyl group, a (trimethylsilyl)methyl group, a 2-phenylethyl group, a 2-aminoethyl group, a 3-phenylpropyl group, and the like.

Specific examples of the unsubstituted aryl group having 4 to 18 carbon atoms represented by R¹¹ to R¹⁵ in the general formulas (2a) and (2b) include a phenyl group, a 1-naphthyl group, a 2-naphthyl group, a 1-anthryl group, a 1-phenanthryl group, a furanyl group, a thiophenyl group, and the like.

Examples of the substituted aryl group having 4 to 18 carbon atoms represented by R¹¹ to R¹⁵ in the general formulas (2a) and (2b) include a group obtained by substituting at least one hydrogen atom of the unsubstituted aryl group with a linear, branched, or cyclic alkyl group; a group that includes a heteroatom (e.g., halogen atom, oxygen atom, nitrogen atom, sulfur atom, phosphorus atom, or silicon atom); or the like. Specific examples of such a group include an o-tolyl group, an m-tolyl group, a p-tolyl group, a 4-hydroxyphenyl group, a 4-methoxyphenyl group, a mesityl group, an o-cumenyl group, a 2,3-xylyl group, a 2,4-xylyl group, a 2,5-xylyl group, a 2,6-xylyl group, a 3,4-xylyl group, a 3,5-xylyl group, a 4-fluorophenyl group, a 4-trifluoromethylphenyl group, a 4-chlorophenyl group, a 4-bromophenyl group, a 4-iodophenyl group, and the like.

Preferable examples of the cyclic group that is formed by at least two of R¹¹, R¹², and R¹³ in the general formula (2a) and includes the sulfonium cation, and the cyclic group that is formed by R¹⁴ and R¹⁵ in the general formula (2b) and includes the iodonium cation include five- to seven-membered ring structures, and the like.

Preferable examples of the sulfonium cation shown by the general formula (2a) include sulfonium cations shown by the following formulas (2a-1) to (2a-64).

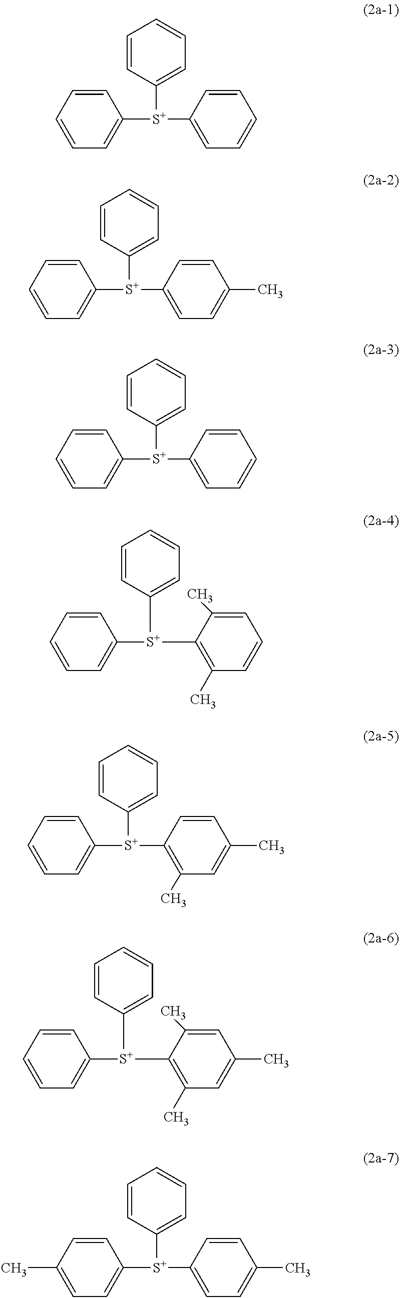

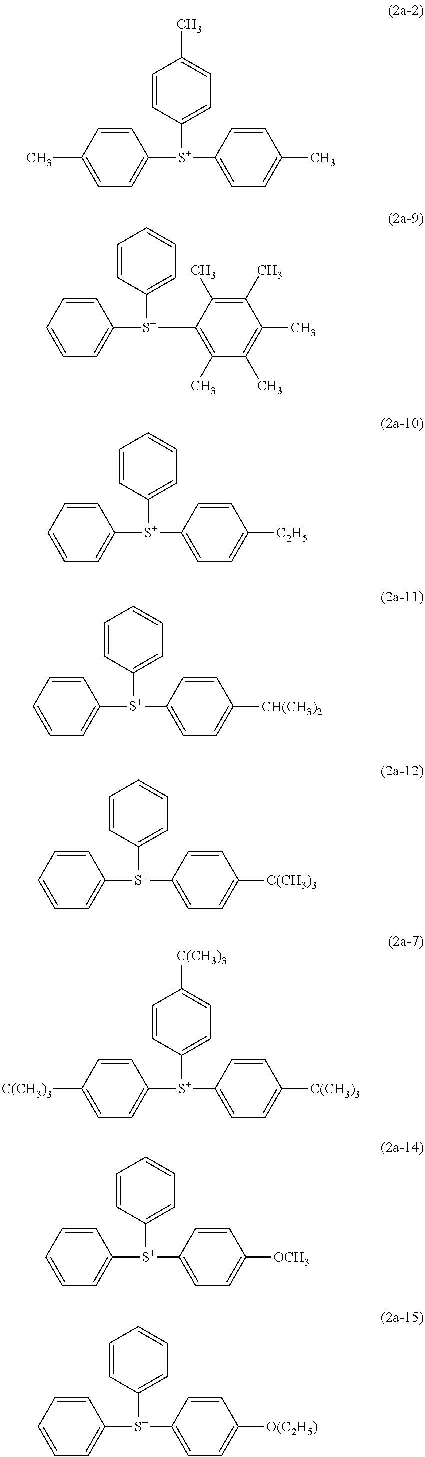

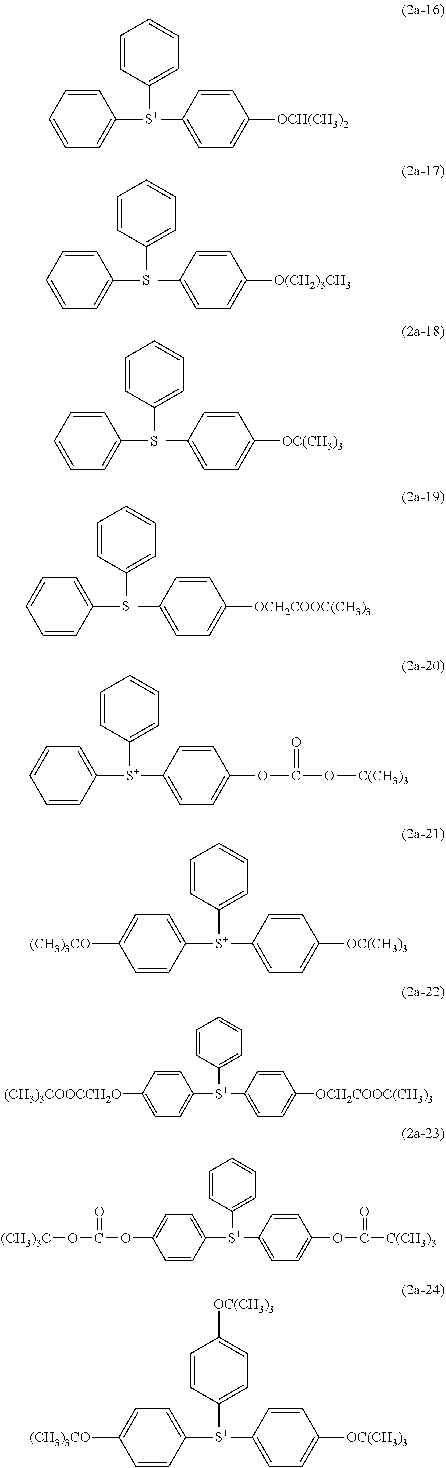

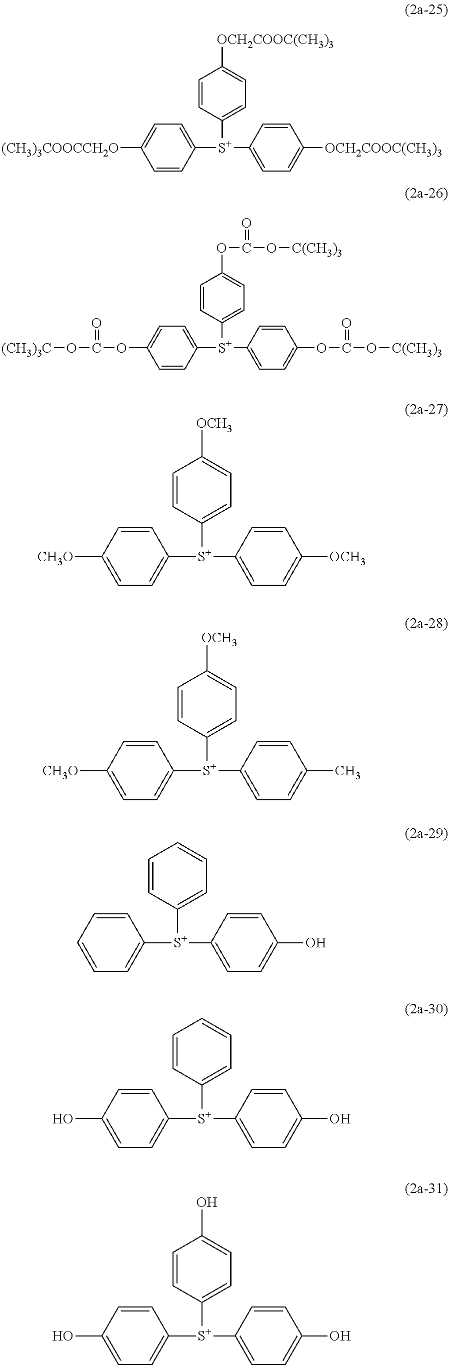

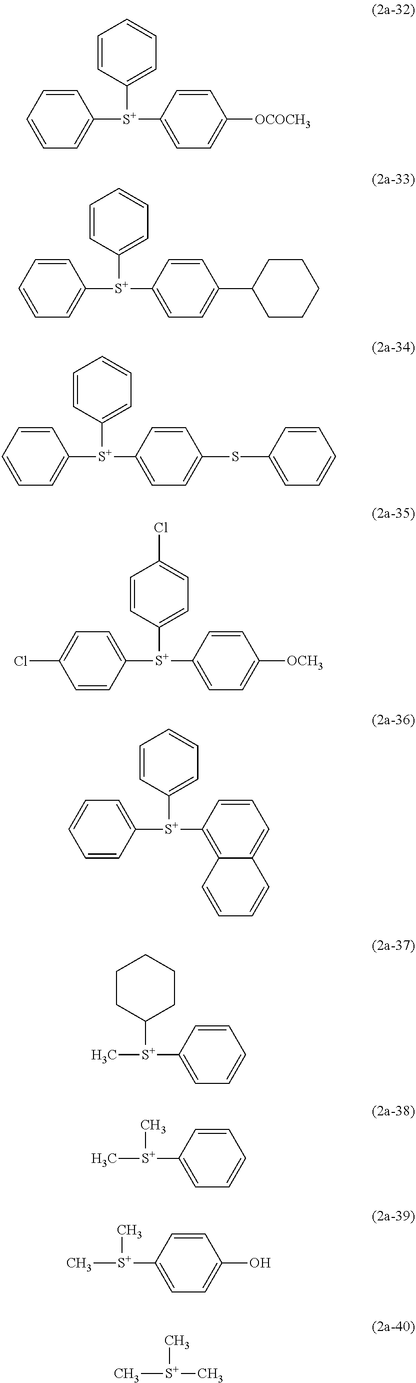

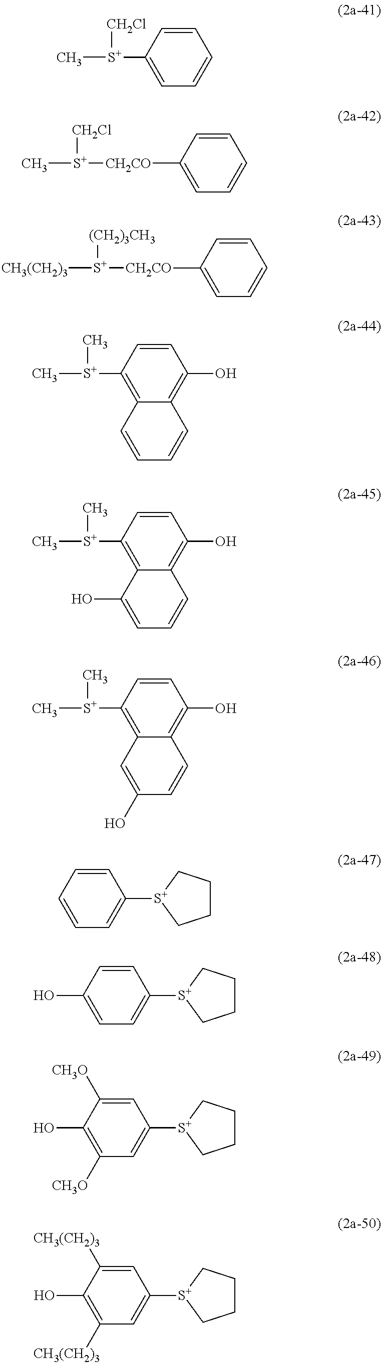

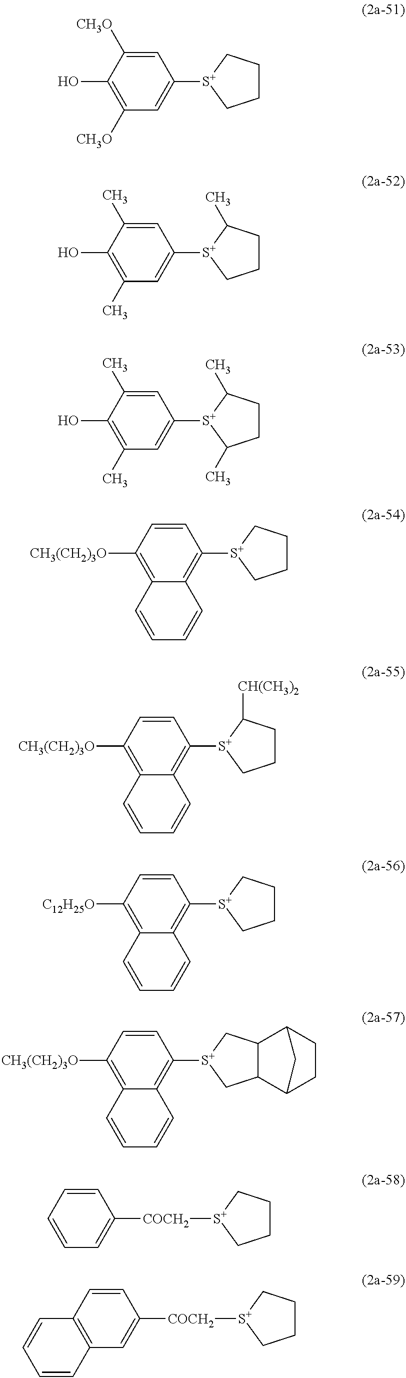

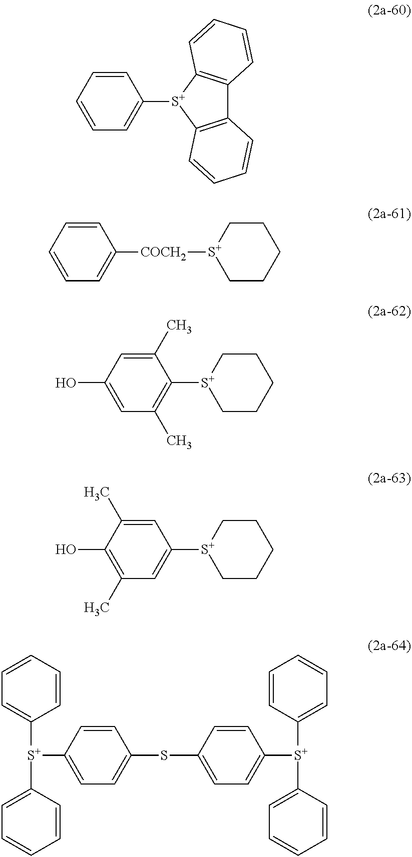

Preferable examples of the iodonium cation shown by the general formula (2b) include iodonium cations shown by the following formulas (2b-1) to (2b-39).

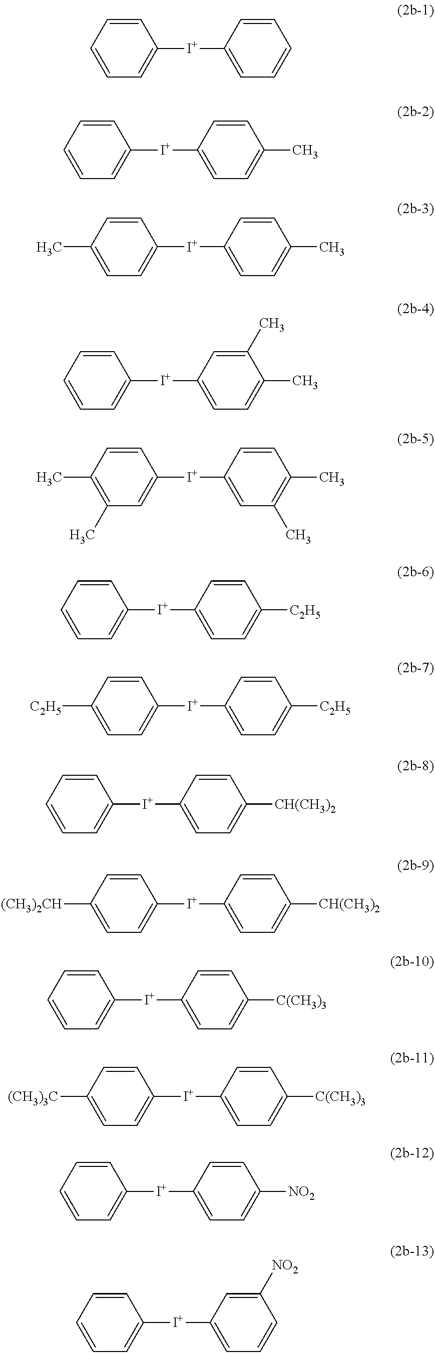

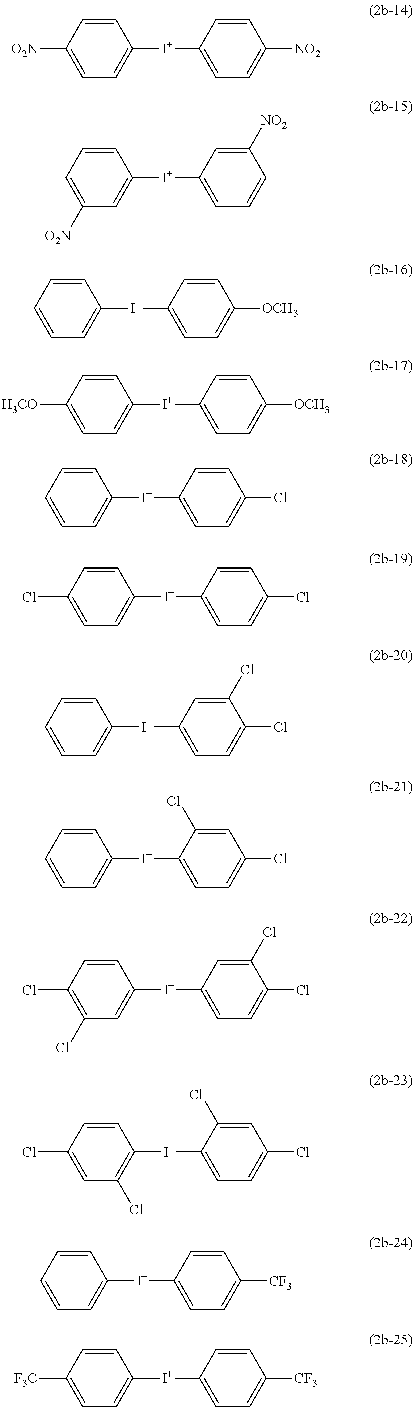

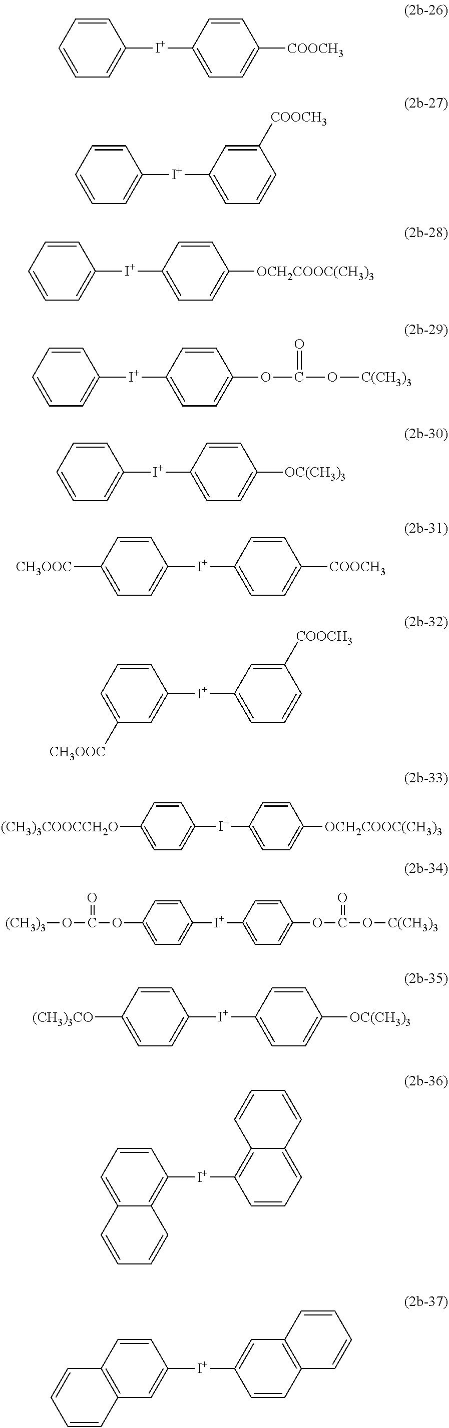

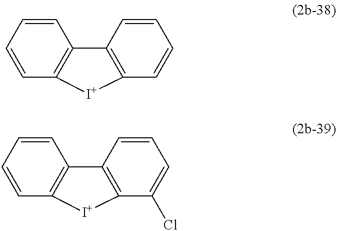

A monomer that produces the repeating unit (1-2) preferably has a structure shown by the following general formula (1-2-1), (1-2-2), or (1-2-3).

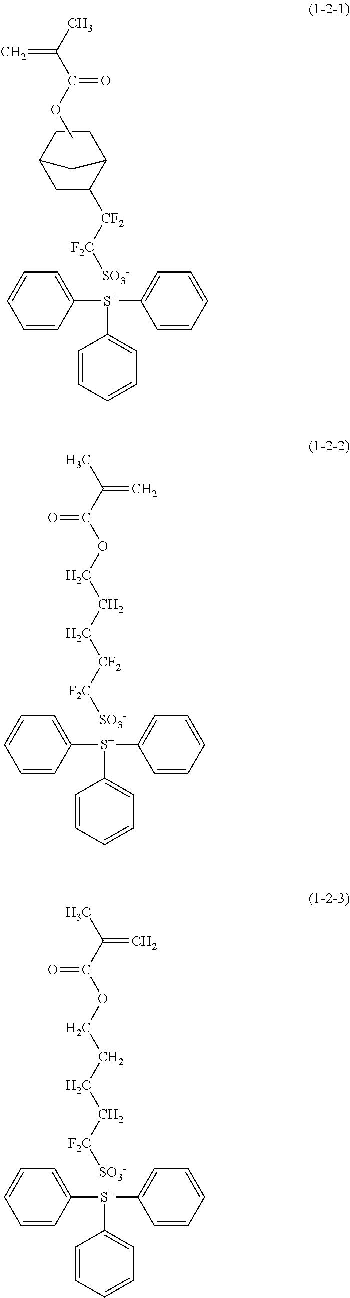

The polymer (A) may include only one type of repeating unit (1), or may include two or more types of repeating units (1).

### A-2. Repeating Units (2) to (4)

The repeating unit (2) that may be included in the polymer (A) is shown by the following general formula (2), and includes a cyclic carbonate structure. The repeating unit (3) is shown by the following general formula (3), and includes a lactone structure. The repeating unit (4) is shown by the following general formula (4), and includes a lactone structure.

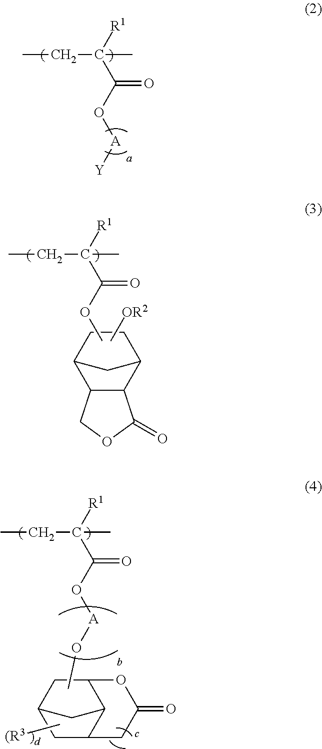

wherein R² represents a hydrogen atom, a methyl group, or a trifluoromethyl group, A represents a methylene group, a linear or branched alkylene group having 2 to 10 carbon atoms, or an arylene group having 3 to 10 carbon atoms, Y represents a group that includes a structure shown by the following general formula (i), a is 0 or 1, R³ represents a linear or branched alkyl group having 1 to 10 carbon atoms, b is an integer from 2 to 4, and c is 0 or 3.

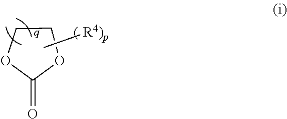

wherein R⁴ represents a hydrogen atom or a linear or branched alkyl group having 1 to 5 carbon atoms, p is 1 or 2, and q is 1 or 2, and two R⁴ may be the same or different when p is 2.

Specific examples of the linear or branched alkylene group having 2 to 10 carbon atoms represented by A in the general formulas (2) and (4) include an ethylene group, a 1,3-propylene group, a 1,2-propylene group, a butylene group, a pentamethylene group, a hexamethylene group, a heptamethylene group, an octamethylene group, a nonamethylene group, a decamethylene group, a 1-methyl-1,3-propylene group, a 2-methyl-1,3-propylene group, a 2-methyl-1,2-propylene group, a 1-methyl-1,4-butylene group, a 2-methyl-1,4-butylene group, and the like. Specific examples of the arylene group having 3 to 10 carbon atoms include a phenylene group, a naphthylene group, an anthrylene group, a phenanthrylene group, and the like.

Specific examples of the linear or branched alkyl group having 1 to 10 carbon atoms represented by R³ in the general formula (3) include a methyl group, an ethyl group, an n-propyl group, an i-propyl group, an n-butyl group, a 2-methylpropyl group, a 1-methylpropyl group, a t-butyl group, an n-pentyl group, an n-hexyl group, a hydroxymethyl group, a hydroxyethyl group, a trifluoromethyl group, and the like. At least one hydrogen atom of these alkyl groups may be substituted with a halogen atom or the like.

The group that has a structure shown by the general formula (i) includes at least a cyclic carbonate structure. The group that has a structure shown by the general formula (i) may be directly bonded to A, or may form a polycyclic structure that includes a cyclic carbonate structure, for example.

Specific examples of the linear or branched alkyl group having 1 to 5 carbon atoms represented by R⁴ in the general formula (i) include linear alkyl groups having 1 to 5 carbon atoms, such as a methyl group, an ethyl group, a propyl group, and a butyl group; branched alkyl groups having 3 to 5 carbon atoms, such as an isopropyl group, an isobutyl group, and a t-butyl group; and the like.

q in the general formula (i) is 1 or 2. Specifically, the cyclic carbonate structure shown by the general formula (i) is a five-membered ring structure when q is 1, and is a six-membered ring structure when q is 2.

The repeating unit (2) preferably has a structure among the structures shown by the following general formulas (2-1) to (2-21).

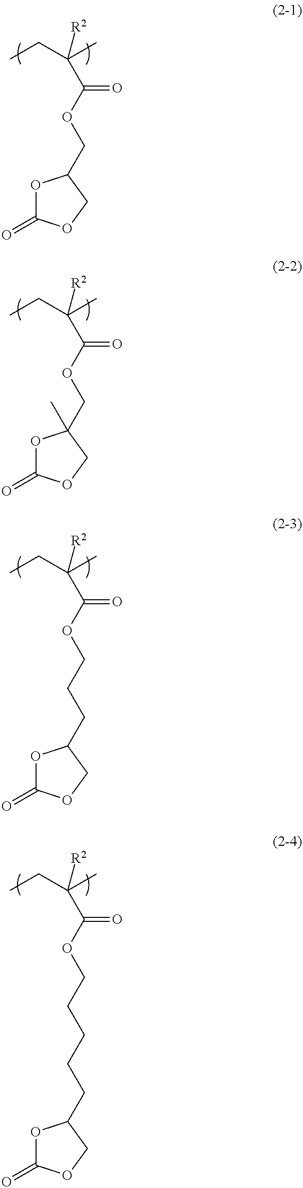

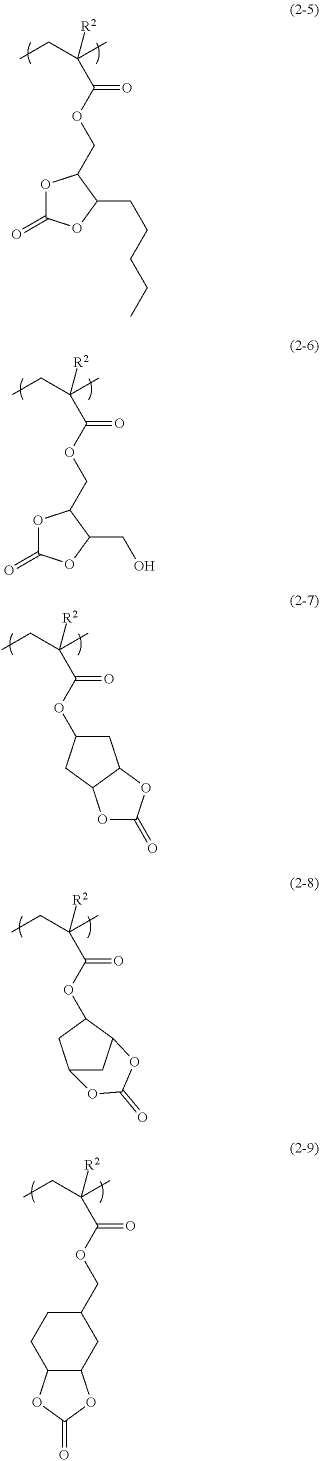

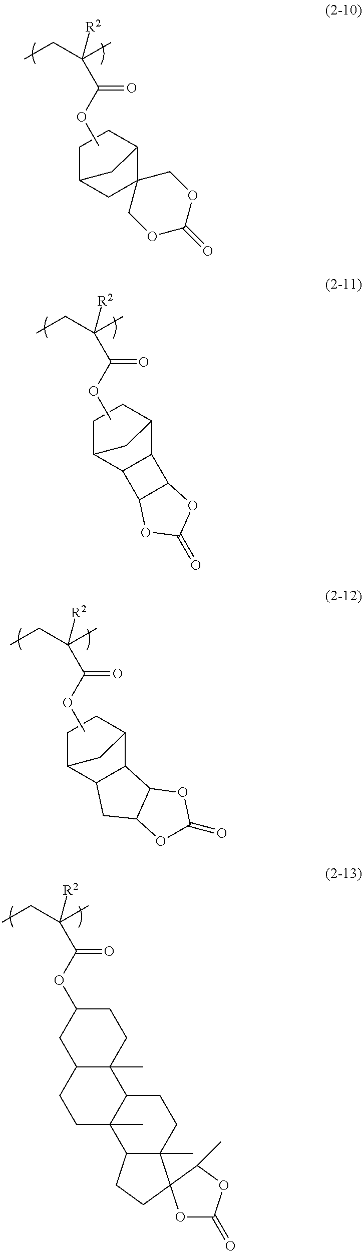

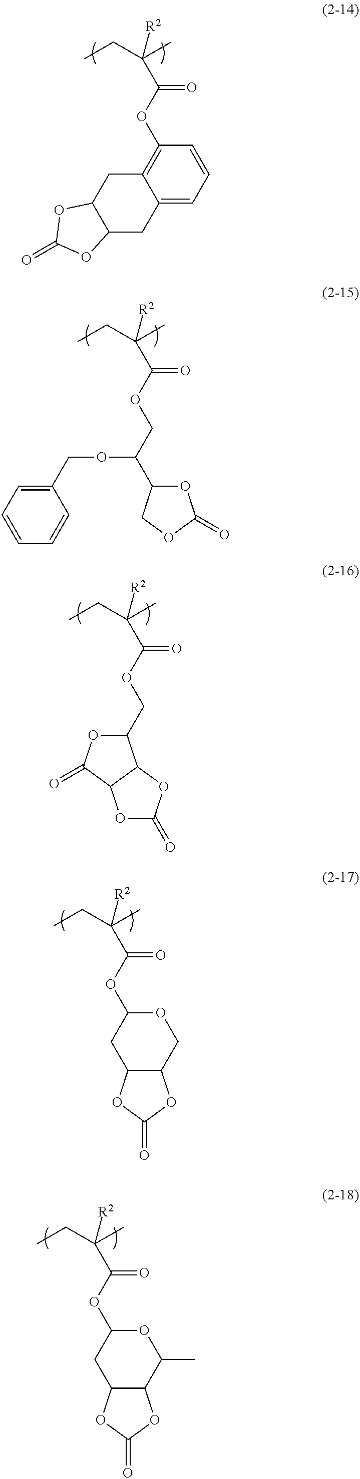

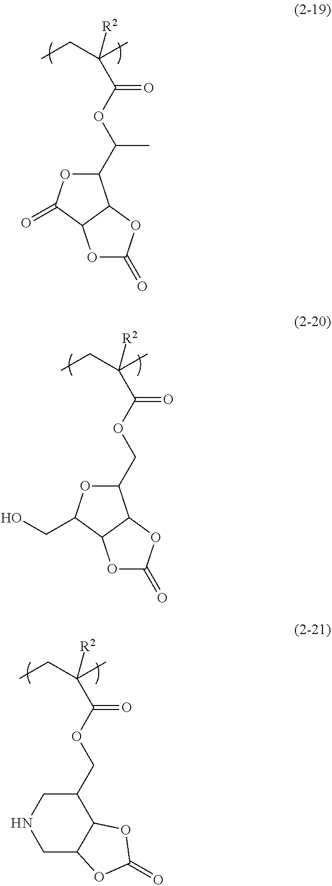

wherein R² is the same as defined for the general formula (2).

The polymer (A) may include only one type of repeating unit among the repeating units shown by the general formulas (2-1) to (2-21), or may include two or more types of repeating units among the repeating units shown by the general formulas (2-1) to (2-21).

The repeating unit (3) preferably has a structure among the structures shown by the following general formulas (3-1) to (3-6).

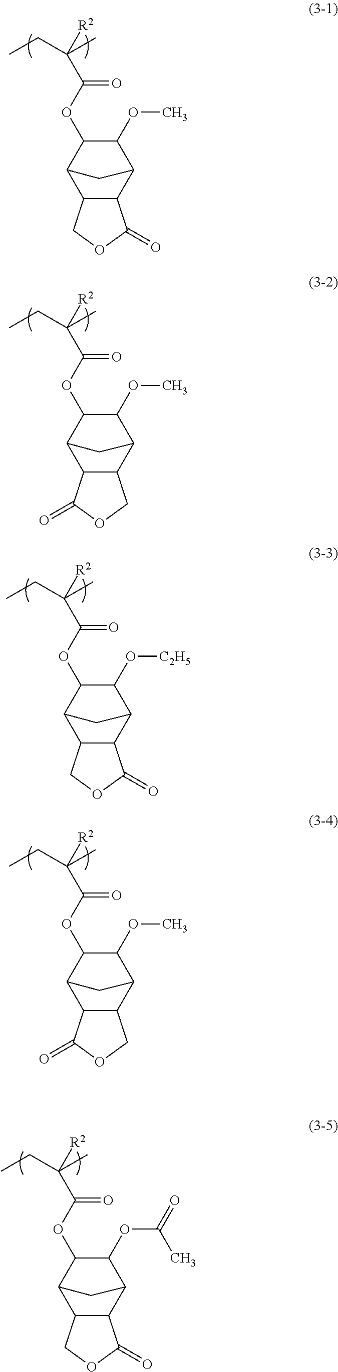

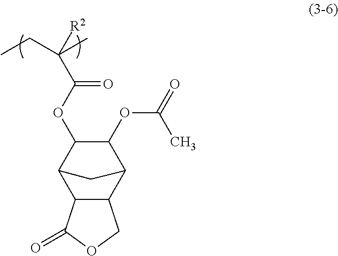

wherein R² is the same as defined for the general formula (3).

The polymer (A) may include only one type of repeating unit among the repeating units shown by the general formulas (3-1) to (3-6), or may include two or more types of repeating units among the repeating units shown by the general formulas (3-1) to (3-6).

The repeating unit (4) preferably has a structure among the structures shown by the following general formulas (4-1) to (4-3).

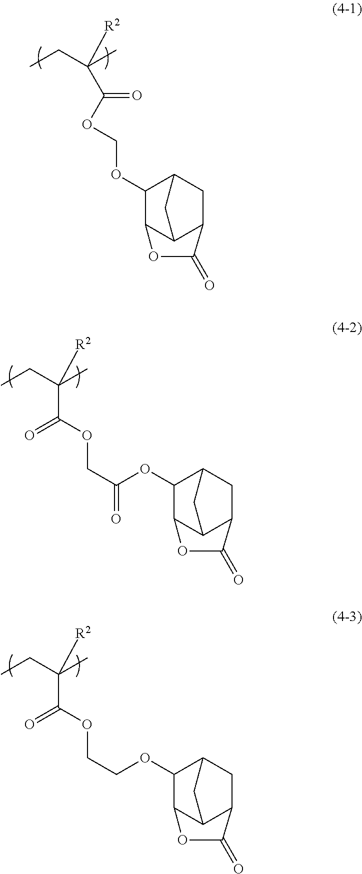

wherein R² is the same as defined for the general formula (4).

The polymer (A) may include only one type of repeating unit among the repeating units shown by the general formulas (4-1) to (4-3), or may include two or more types of repeating units among the repeating units shown by the general formulas (4-1) to (4-3).

### A-3. Repeating Unit (5)

The polymer (A) preferably further includes a repeating unit (5) shown by the following general formula (5).

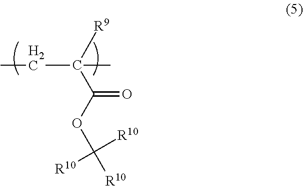

wherein R⁹ represents a hydrogen atom, a methyl group, or a trifluoromethyl group, and R¹⁰ represent a monovalent alicyclic hydrocarbon group having 4 to 20 carbon atoms, a derivative thereof, or a linear or branched alkyl group having 1 to 4 carbon atoms, and two of R¹⁰ may bond to form an alicyclic hydrocarbon group having 4 to 20 carbon atoms or a derivative thereof.

Specific examples of the monovalent alicyclic hydrocarbon group having 4 to 20 carbon atoms represented by R¹⁰ in the general formula (5) include cycloalkanes such as cyclobutane, cyclopentane, cyclohexane, cycloheptane, and cyclooctane; and groups derived from cycloalkanes such as a norbornane, tricyclodecane, tetracyclododecane, and adamantane.

Examples of a derivative of the monovalent alicyclic hydrocarbon group having 4 to 20 carbon atoms represented by R¹⁰ in the general formula (5) include groups obtained by substituting at least one hydrogen atom of the alicyclic hydrocarbon group with at least one linear or branched alkyl group having 1 to 4 carbon atoms such as a methyl group, an ethyl group, an n-propyl group, an i-propyl group, an n-butyl group, a 2-methylpropyl group, a 1-methylpropyl group, or a t-butyl group.

Among these monovalent alicyclic hydrocarbon groups having 4 to 20 carbon atoms represented by R¹⁰ in the general formula (5) and derivatives thereof, alicyclic hydrocarbon groups derived from norbornane, tricyclodecane, tetracyclododecane, adamantane, cyclopentane, cyclohexane, etc., or groups obtained by substituting these alicyclic hydrocarbon groups with the above alkyl group are preferable.

Specific examples of the linear or branched alkyl group having 1 to 4 carbon atoms represented by R¹⁰ in the general formula (5) include a methyl group, an ethyl group, an n-propyl group, an i-propyl group, an n-butyl group, a 2-methylpropyl group, a 1-methylpropyl group, a t-butyl group, and the like.

Examples of the alicyclic hydrocarbon group having 4 to 20 carbon atoms formed by two R¹⁰ in the general formula (5) include a cyclobutyl group, a cyclopentyl group, a cyclohexyl group, a cyclooctyl group, and the like.

Examples of a derivative of the monovalent alicyclic hydrocarbon group having 4 to 20 carbon atoms formed by two R¹⁰ in the general formula (5) include groups obtained by substituting at least one hydrogen atom of the alicyclic hydrocarbon group with at least one linear or branched alkyl group having 1 to 4 carbon atoms such as a methyl group, an ethyl group, an n-propyl group, an i-propyl group, an n-butyl group, a 2-methylpropyl group, a 1-methylpropyl group, or a t-butyl group.

Among these alicyclic hydrocarbon groups having 4 to 20 carbon atoms formed by two R¹⁰ in the general formula (5) and derivatives thereof, a cyclopentyl group, a cyclohexyl group, groups obtained by substituting these divalent alicyclic hydrocarbon groups with the above alkyl group, and the like are preferable.

Preferable examples of the group shown by —C(R¹⁰)₃ in the general formula (5) include a t-butyl group, a 1-n-(1-ethyl-1-methyl)propyl group, a 1-n-(1,1-dimethyl)propyl group, a 1-n-(1,1-dimethyl)butyl group, a 1-n-(1,1-dimethyl)pentyl group, a 1-n-(1,1-diethyl)propyl group, a 1-n-(1,1-diethyl)butyl group, a 1-n-(1,1-diethyl)pentyl group, a 1-(1-methyl)cyclopentyl group, a 1-(1-ethyl)cyclopentyl group, a 1-(1-n-propyl)cyclopentyl group, a 1-(1-i-propyl)cyclopentyl group, a 1-(1-methyl)cyclohexyl group, a 1-(1-ethyl)cyclohexyl group, a 1-(1-n-propyl)cyclohexyl group, a 1-(1-i-propyl)cyclohexyl group, a 1-{1-methyl-1-(2-norbonyl)}ethyl group, a 1-{1-methyl-1-(2-tetracyclodecanyl)}ethyl group, a 1-{1-methyl-1-(1-adamantyl)}ethyl group, a 2-(2-methyl)norbonyl group, a 2-(2-ethyl)norbonyl group, a 2-(2-n-propyl)norbonyl group, a 2-(2-i-propyl)norbonyl group, a 2-(2-methyl)tetracyclodecanyl group, a 2-(2-ethyl)tetracyclodecanyl group, a 2-(2-n-propyl)tetracyclodecanyl group, a 2-(2-i-propyl)tetracyclodecanyl group, a 1-(1-methyl)adamantyl group, a 1-(1-ethyl)adamantyl group, a 1-(1-n-propyl)adamantyl group, a 1-(1-i-propyl)adamantyl group, and the like. Further preferable examples of the group shown by —C(R¹⁰)₃ in the general formula (5) include groups obtained by substituting at least one hydrogen atom of the alicyclic hydrocarbon groups with at least one linear or branched alkyl group having 1 to 4 carbon atoms such as a methyl group, an ethyl group, an n-propyl group, an i-propyl group, an n-butyl group, a 2-methylpropyl group, a 1-methylpropyl group, or a t-butyl group.

### A-4. Additional Repeating Unit

The polymer (A) may include an additional repeating unit other than the repeating units (1) to (5).

Examples of a monomer that produces the additional repeating unit include polycyclic cycloalkyl (meth)acrylates having 7 to 20 carbon atoms such as bicyclo[2.2.1]heptyl (meth)acrylate, cyclohexyl (meth)acrylate, bicyclo[4.4.0]decanyl (meth)acrylate, bicyclo[2.2.2]octyl (meth)acrylate, tricyclo[5.2.1.0^{2,6}]decanyl (meth)acrylate, tetracyclo[6.2.1.1^{3,6}.0^{2,7}]dodecanyl (meth)acrylate, and tricyclo[3.3.1.1^{3,7}]decanyl (meth)acrylate;

(meth)acrylates having a hydroxyadamantane structure such as 3-hydroxyadamantan-1-ylmethyl (meth)acrylate, 3,5-dihydroxyadamantan-1-ylmethyl (meth)acrylate, 3-hydroxy-5-methyladamantan-1-yl (meth)acrylate, 3,5-dihydroxy-7-methyladamantan-1-yl (meth)acrylate, 3-hydroxy-5,7-dimethyladamantan-1-yl (meth)acrylate, and 3-hydroxy-5,7-dimethyladamantan-1-ylmethyl (meth)acrylate;
(meth)acrylates having a bridged hydrocarbon skeleton such as dicyclopentenyl (meth)acrylate and adamantylmethyl (meth)acrylate; carboxyl group-containing esters having a bridged hydrocarbon skeleton such as carboxynorbornyl (meth)acrylate, carboxytricyclodecanyl (meth)acrylate, and carboxytetracycloundecanyl (meth)acrylate;
(meth)acrylates that do not have a bridged hydrocarbon skeleton such as methyl (meth)acrylate, ethyl (meth)acrylate, n-propyl (meth)acrylate, n-butyl (meth)acrylate, 2-methylpropyl (meth)acrylate, 1-methylpropyl (meth)acrylate, t-butyl (meth)acrylate, 2-hydroxyethyl (meth)acrylate, 2-hydroxypropyl (meth)acrylate, 3-hydroxypropyl (meth)acrylate, cyclopropyl (meth)acrylate, cyclopentyl (meth)acrylate, cyclohexyl (meth)acrylate, 4-methoxycyclohexyl (meth)acrylate, 2-cyclopentyloxycarbonylethyl (meth)acrylate, 2-cyclohexyloxycarbonylethyl (meth)acrylate, and 2-(4-methoxycyclohexyl)oxycarbonylethyl (meth)acrylate;
α-hydroxymethylacrylates such as methyl α-hydroxymethylacrylate, ethyl α-hydroxymethylacrylate, n-propyl α-hydroxymethylacrylate, and n-butyl-α-hydroxymethylacrylate; unsaturated nitrile compounds such as (meth)acrylonitrile, α-chloroacrylonitrile, crotonitrile, maleinitrile, fumarnitrile, mesaconitrile, citraconitrile, and itaconitrile; unsaturated amide compounds such as (meth)acrylamide, N,N-dimethyl (meth)acrylamide, crotonamide, maleinamide, fumaramide, mesaconamide, citraconamide, and itaconamide; other nitrogen-containing vinyl compounds such as N-(meth)acryloylmorpholine, N-vinyl-epsilon-caprolactam, N-vinylpyrrolidone, vinylpyridine, and vinylimidazole; unsaturated carboxylic acids (anhydrides) such as (meth)acrylic acid, crotonic acid, maleic acid, maleic anhydride, fumaric acid, itaconic acid, itaconic anhydride, citraconic acid, citraconic anhydride, and mesaconic acid; carboxyl group-containing esters such as 2-carboxyethyl (meth)acrylate, 2-carboxypropyl (meth)acrylate, 3-carboxypropyl (meth)acrylate, 4-carboxybutyl (meth)acrylate, and 4-carboxycyclohexyl (meth)acrylate;
esters that include a fluorine atom and a hydroxyl group such as 3-(1,1,1-trifluoro-2-trifluoromethyl-2-hydroxy)propyl (meth)acrylate, 4-(1,1,1-trifluoro-2-trifluoromethyl-2-hydroxy)butyl (meth)acrylate, 5-(1,1,1-trifluoro-2-trifluoromethyl-2-hydroxy)pentyl (meth)acrylate, 4-(1,1,1-trifluoro-2-trifluoromethyl-2-hydroxy)pentyl (meth)acrylate, 2-[5-(1′,1′,1′-trifluoro-2′-trifluoromethyl-2′-hydroxy)propyl]bicyclo[2.2.1]heptyl (meth)acrylate, and
3-[8-(1′,1′,1′-trifluoro-2′-trifluoromethyl-2′-hydroxy)propyl]tetracyclo[6.2.1.1^{3,6}.0^{2,7}] dodecyl (meth)acrylate;
polyfunctional monomers such as methylene glycol di(meth)acrylate, ethylene glycol di(meth)acrylate, propylene glycol di(meth)acrylate, 1,6-hexanediol di(meth)acrylate, 2,5-dimethyl-2,5-hexanediol di(meth)acrylate, 1,8-octanediol di(meth)acrylate, 1,9-nonanediol di(meth)acrylate, 1,4-bis(2-hydroxypropyl)benzene di(meth)acrylate, 1,3-bis(2-hydroxypropyl)benzene di(meth)acrylate, 1,2-adamantanediol di(meth)acrylate, 1,3-adamantanediol di(meth)acrylate, 1,4-adamantanediol di(meth)acrylate, tricyclodecanyldimethylol di(meth)acrylate; and the like.

### A-5. Preparation of Polymer (A)

The polymer (A) may be prepared by polymerizing the polymerizable unsaturated monomers that produce the respective repeating units in an appropriate solvent optionally in the presence of a chain transfer agent using a radical polymerization initiator such as a hydroperoxide, a dialkyl peroxide, a diacyl peroxide, or an azo compound, for example.

The content of the repeating unit (1) in the polymer (A) is preferably 0.1 to 50 mol %, more preferably 0.5 to 40 mol %, and particularly preferably 1 to 35 mol %, based on the total amount of the repeating units. If the content of the repeating unit (1) is less than 1 mol %, the resolution may decrease. If the content of the repeating unit (1) is more than 50 mol %, the solubility of the polymer (A) in an alkaline developer may decrease so that development defects may occur.

The content of the repeating units (2) to (4) in the polymer (A) is preferably 1 to 50 mol %, more preferably 2 to 40 mol %, and particularly preferably 3 to 30 mol %, based on the total amount of the repeating units. If the content of the repeating units (2) to (4) is less than 1 mol %, the resolution may decrease. If the content of the repeating units (2) to (4) is more than 50 mol %, the solubility of the polymer (A) in an alkaline developer may increase so that the pattern may be dissolved.

The content of the repeating unit (5) in the polymer (A) is preferably 10 to 80 mol %, more preferably 15 to 75 mol %, and particularly preferably 20 to 70 mol %, based on the total amount of the repeating units. If the content of the repeating unit (5) is less than 10 mol %, the resolution may decrease. If the content of the repeating unit (5) is more than 80 mol %, the solubility of the polymer (A) in an alkaline developer may increase so that the pattern may be dissolved.

Specific examples of the solvent used when preparing the polymer (A) include linear alkanes such as n-pentane, n-hexane, n-heptane, n-octane, n-nonane, and n-decane; cycloalkanes such as cyclohexane, cycloheptane, cyclooctane, decalin, and norbornane; aromatic hydrocarbons such as benzene, toluene, xylene, ethylbenzene, and cumene; halogenated hydrocarbons such as chlorobutanes, bromohexanes, dichloroethanes, hexamethylene dibromide, and chlorobenzene; saturated carboxylic acid esters such as ethyl acetate, n-butyl acetate, i-butyl acetate, and methyl propionate; ketones such as acetone, 2-butanone, 4-methyl-2-pentanone, and 2-heptanone; ethers such as tetrahydrofuran, dimethoxyethanes, and diethoxyethanes; alcohols such as methanol, ethanol, 1-propanol, 2-propanol, and 4-methyl-2-pentanol; and the like. These polymerization solvents may be used either individually or in combination.

The reaction temperature employed when preparing the polymer (A) is normally 40 to 150° C., and preferably 50 to 120° C. The reaction time is normally 1 to 48 hours, and preferably 1 to 24 hours.

The polystyrene-reduced weight average molecular weight (Mw) of the polymer (A) determined by gel permeation chromatography (GPC) is preferably 1000 to 50,000, more preferably 1000 to 40,000, and still more preferably 1000 to 30,000. If the Mw of the polymer (A) is less than 1000, a sufficient receding contact angle may not be obtained. If Mw of the polymer (A) is more than 50,000, the developability of the resulting resist may decrease.

The ratio (Mw/Mn) of the Mw to the polystyrene-reduced number average molecular weight (Mn) of the polymer (A) determined by GPC is normally 1 to 5, and preferably 1 to 4.

It is preferable that the content of impurities (e.g., halogen and metal) in the polymer (A) be 0.5 mass% or less. If the content of impurities in the polymer (A) is 0.5 mass% or less, the sensitivity, the resolution, the process stability, the pattern shape, etc., of a resist formed using the radiation-sensitive resin composition that includes the polymer (A) are further improved.

The polymer (A) may be purified by a chemical purification method (e.g., washing with water or liquid-liquid extraction), or a combination of the chemical purification method and a physical purification method (e.g., ultrafiltration or centrifugation), for example.

The radiation-sensitive resin composition according to one embodiment of the invention may include only one type of polymer (A), or may include two or more types of polymers (A).

### B. Solvent (B)

The radiation-sensitive resin composition according to one embodiment of the invention is prepared as a resin composition solution by dissolving the polymer (A) in the solvent (B).

The resin composition solution normally has a solid content of 1 to 50 mass %, and preferably 1 to 25 mass %. The resin composition solution is filtered through a filter having a pore size of about 0.2 μm, for example.

Specific examples of the solvent (B) include linear or branched ketones such as 2-butanone, 2-pentanone, 3-methyl-2-butanone, 2-hexanone, 4-methyl-2-pentanone, 3-methyl-2-pentanone, 3,3-dimethyl-2-butanone, 2-heptanone, and 2-octanone; cyclic ketones such as cyclopentanone, 3-methylcyclopentanone, cyclohexanone, 2-methylcyclopentanone, 2,6-dimethylcyclohexanone, and isophorone; propylene glycol monoalkyl ether acetates such as propylene glycol monomethyl ether acetate, propylene glycol monoethyl ether acetate, propylene glycol mono-n-propyl ether acetate, propylene glycol mono-i-propyl ether acetate, propylene glycol mono-n-butyl ether acetate, propylene glycol mono-i-butyl ether acetate, propylene glycol mono-sec-butyl ether acetate, and propylene glycol mono-t-butyl ether acetate; alkyl 2-hydroxypropionates such as methyl 2-hydroxypropionate, ethyl 2-hydroxypropionate, n-propyl 2-hydroxypropionate, i-propyl 2-hydroxypropionate, n-butyl 2-hydroxypropionate, i-butyl 2-hydroxypropionate, sec-butyl 2-hydroxypropionate, and t-butyl 2-hydroxypropionate; alkyl 3-alkoxypropionates such as methyl 3-methoxypropionate, ethyl 3-methoxypropionate, methyl 3-ethoxypropionate, and ethyl 3-ethoxypropionate;

n-propyl alcohol, i-propyl alcohol, n-butyl alcohol, t-butyl alcohol, cyclohexanol, ethylene glycol monomethyl ether, ethylene glycol monoethyl ether, ethylene glycol mono-n-propyl ether, ethylene glycol mono-n-butyl ether, diethylene glycol dimethyl ether, diethylene glycol diethyl ether, diethylene glycol di-n-propyl ether, diethylene glycol di-n-butyl ether, ethylene glycol monomethyl ether acetate, ethylene glycol monoethyl ether acetate, ethylene glycol mono-n-propyl ether acetate, propylene glycol monomethyl ether, propylene glycol monoethyl ether, propylene glycol mono-n-propyl ether, toluene, xylene, ethyl 2-hydroxy-2-methylpropionate, ethyl ethoxyacetate, ethyl hydroxyacetate, methyl 2-hydroxy-3-methylbutyrate, 3-methoxybutylacetate, 3-methyl-3-methoxybutylacetate, 3-methyl-3-methoxybutylpropionate, 3-methyl-3-methoxybutylbutyrate, ethyl acetate, n-propyl acetate, n-butyl acetate, methyl acetoacetate, ethyl acetoacetate, methyl pyruvate, ethyl pyruvate, N-methylpyrrolidone, N,N-dimethylformamide, N,N-dimethylacetamide, benzyl ethyl ether, di-n-hexyl ether, diethylene glycol monomethyl ether, diethylene glycol monoethyl ether, caproic acid, caprylic acid, 1-octanol, 1-nonanol, benzyl alcohol, benzyl acetate, ethyl benzoate, diethyl oxalate, diethyl maleate, γ-butyrolactone, ethylene carbonate, propylene carbonate; and the like.

Among these, linear or branched ketones, cyclic ketones, propylene glycol monoalkyl ether acetates, alkyl 2-hydroxypropionates, alkyl 3-alkoxypropionates, γ-butyrolactone, and the like are preferable. These solvents (B) may be used either individually or in combination.

### C. Nitrogen-Containing Compound (C)

It is preferable that the radiation-sensitive resin composition according to one embodiment of the invention include (C) a nitrogen-containing compound as an additive.

The nitrogen-containing compound (C) controls a phenomenon in which an acid generated from the photoacid-generating group included in the polymer (A) upon exposure is diffused in the resist film, and hinders undesired chemical reactions in the unexposed area. The nitrogen-containing compound (C) (i.e., acid diffusion controller) improves the resolution of the resist, and suppresses a change in line width of the resist pattern due to a change in post-exposure delay (PED) from exposure to post-exposure bake, so that a composition that exhibits remarkably superior process stability can be obtained. The storage stability of the radiation-sensitive resin composition is also improved by adding the nitrogen-containing compound (C) (i.e., acid diffusion controller).

Examples of the nitrogen-containing compound (C) include tertiary amine compounds, amine compounds other than tertiary amine compounds, amide group-containing compounds, urea compounds, nitrogen-containing heterocyclic compounds, and the like. The nitrogen-containing compounds (C) may be used either individually or in combination.

The content of the nitrogen-containing compound (C) in the radiation-sensitive resin composition is normally 0.001 to 15 parts by mass, preferably 0.001 to 10 parts by mass, and more preferably 0.001 to 5 parts by mass, based on 100 parts by mass of the polymer (A). If the content of the nitrogen-containing compound (C) exceeds 15 parts by mass, the sensitivity of the resulting resist may decrease. If the content of the acid diffusion controller (C) is less than 0.001 parts by mass, the pattern shape and the dimensional accuracy of the resulting resist may decrease depending on the process conditions.

### D. Additional Acid Generator (D)

The radiation-sensitive resin composition according to one embodiment of the invention may include a photoacid generator (hereinafter may be referred to as “additional acid generator (D)”) as an additive in addition to the photoacid-generating group included in the polymer (A).

Examples of the additional acid generator (D) include onium salt compounds such as iodonium salts, sulfonium salts, phosphonium salts, diazonium salts, and pyridinium salts; sulfonic acid compounds such as alkyl sulfonates, alkylimide sulfonates, haloalkyl sulfonates, aryl sulfonates, and imino sulfonates; and the like.

Specific examples of the onium salt compounds include diphenyliodonium trifluoromethanesulfonate, diphenyliodonium nonafluoro-n-butanesulfonate, diphenyliodonium perfluoro-n-octanesulfonate, bis(4-t-butylphenyl)iodonium trifluoromethanesulfonate, bis(4-t-butylphenyl)iodonium nonafluoro-n-butanesulfonate, bis(4-t-butylphenyl)iodonium perfluoro-n-octanesulfonate, cyclohexyl-2-oxocyclohexyl-methylsulfonium trifluoromethanesulfonate, dicyclohexyl-2-oxocyclohexylsulfonium trifluoromethanesulfonate, 2-oxocyclohexyldimethylsulfonium trifluoromethanesulfonate, and the like.

Among these, diphenyliodonium trifluoromethanesulfonate, diphenyliodonium nonafluoro-n-butanesulfonate, diphenyliodonium perfluoro-n-octanesulfonate, bis(4-t-butylphenyl)iodonium trifluoromethanesulfonate, bis(4-t-butylphenyl)iodonium nonafluoro-n-butanesulfonate, bis(4-t-butylphenyl)iodonium perfluoro-n-octanesulfonate, cyclohexyl-2-oxocyclohexyl-methylsulfonium trifluoromethanesulfonate, dicyclohexyl-2-oxocyclohexylsulfonium trifluoromethanesulfonate, 2-oxocyclohexyldimethylsulfonium trifluoromethanesulfonate, and the like are preferable.

Specific examples of the sulfonic acid compounds include benzoin tosylate, pyrogallol tris(trifluoromethanesulfonate), nitrobenzyl-9,10-diethoxyanthracene-2-sulfonate, trifluoromethanesulfonylbicyclo[2.2.1]hept-5-ene-2,3-dicarbodiimide, nonafluoro-n-butanesulfonylbicyclo[2.2.1]hept-5-ene-2,3-dicarbodiimide, perfluoro-n-octanesulfonylbicyclo[2.2.1]hept-5-ene-2,3-dicarbodiimide, N-hydroxysuccinimidetrifluoromethanesulfonate, N-hydroxysuccinimidenonafluoro-n-butanesulfonate, N-hydroxysuccinimideperfluoro-n-octanesulfonate, 1,8-naphthalenedicarboxylic acid imide trifluoromethanesulfonate, 1,8-naphthalenedicarboxylic acid imide nonafluoro-n-butanesulfonate, 1,8-naphthalenedicarboxylic acid imide perfluoro-n-octanesulfonate, and the like.

Among these, trifluoromethanesulfonylbicyclo[2.2.1]hept-5-ene-2,3-dicarbodiimide, nonafluoro-n-butanesulfonylbicyclo[2.2.1]hept-5-ene-2,3-dicarbodiimide, perfluoro-n-octanesulfonylbicyclo[2.2.1]hept-5-ene-2,3-dicarbodiimide, N-hydroxysuccinimidetrifluoromethanesulfonate, N-hydroxysuccinimidenonafluoro-n-butanesulfonate, N-hydroxysuccinimideperfluoro-n-octanesulfonate, 1,8-naphthalenedicarboxylic acid imide trifluoromethanesulfonate, and the like are preferable.

These additional acid generators (D) may be used either individually or in combination.

The total content of the repeating unit (1) included in the polymer (A) and the additional acid generator (D) in the radiation-sensitive resin composition is normally 0.5 to 30 parts by mass, and preferably 1 to 25 parts by mass, based on 100 parts by mass of the polymer (A) in order to provide the resulting resist with sensitivity and developability. If the total content of the repeating unit (1) and the additional acid generator (D) is more than 30 parts by mass, the transparency of the resulting resist to radiation may decrease, so that a rectangular resist pattern may not be obtained.

The ratio of the content of the additional acid generator (D) to the total content of the repeating unit (1) included in the polymer (A) and the additional acid generator (D) in the radiation-sensitive resin composition is normally 80 mass % or less, and preferably 60 mass % or less.

### <Formation of Resist Pattern>

The radiation-sensitive resin composition according to one embodiment of the invention is useful as a chemically-amplified resist. When using the radiation-sensitive resin composition as a chemically-amplified resist, the acid-dissociable group included in the repeating unit (1) included in the polymer (A) dissociates due to an acid generated by the photoacid-generating group upon exposure to produce a carboxyl group. As a result, the solubility of the exposed area of the resist in an alkaline developer increases. Therefore, the exposed area is dissolved and removed by the alkaline developer to obtain a positive-tone photoresist pattern.

When forming a resist pattern using the positive-tone radiation-sensitive resin composition according to one embodiment of the invention, the resin composition solution is applied to a substrate (e.g., silicon wafer or aluminum-coated wafer) by an appropriate application method (e.g., rotational coating, cast coating, or roll coating) to form a resist film. After optionally subjecting the resist film to pre-bake (PB), the resist film is exposed through a mask that is designed to form a desired resist pattern. Radiation used for exposure is appropriately selected from visible rays, ultraviolet rays, deep ultraviolet rays, X-rays, charged particle rays, and the like depending on the type of acid generator. It is preferable to use deep ultraviolet rays such as ArF excimer laser light (wavelength: 193 nm) or KrF excimer laser light (wavelength: 248 nm). It is particularly preferable to use ArF excimer laser light (wavelength: 193 nm). The exposure conditions (e.g., dose) are appropriately selected depending on the composition of the radiation-sensitive resin composition, etc. It is preferable to perform post-exposure bake (PEB) after exposure. The acid-dissociable group included in the resin component smoothly dissociates by performing PEB. The PEB temperature is determined depending on the composition of the radiation-sensitive resin composition, but is normally 30 to 200° C., and preferably 50 to 170° C.

In order to bring out the potential of the radiation-sensitive resin composition to a maximum extent, an organic or inorganic antireflective film may be formed on a substrate, as disclosed in Japanese Examined Patent Publication (KOKOKU) No. 6-12452 (Japanese Patent Application Publication (KOKAI) No. 59-93448), for example. A protective film may be formed on the resist film so that the resist film is not affected by basic impurities, etc., contained in the environmental atmosphere, as disclosed in Japanese Patent Application Publication (KOKAI) No. 5-188598, for example. In order to prevent outflow of the acid generator, etc., from the resist film during liquid immersion lithography, a liquid immersion lithography protective film may be formed on the resist film, as disclosed in Japanese Patent Application Publication (KOKAI) No. 2005-352384, for example. Note that these methods may be used either individually or in combination.

The resist film thus exposed is developed to form a given resist pattern. An alkaline aqueous solution prepared by dissolving at least one alkaline compound (e.g., sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethylamine, ethyldimethylamine, triethanolamine, tetramethylammonium hydroxide, pyrrole, piperidine, choline, 1,8-diazabicyclo-[5.4.0]-7-undecene, or 1,5-diazabicyclo-[4.3.0]-5-nonene) in water is preferably used as the developer. The concentration of the alkaline aqueous solution is normally 10 mass % or less. If the concentration of the aqueous alkaline solution exceeds 10 mass %, an unexposed area may also be dissolved in the developer.

An organic solvent may be added to the developer (alkaline aqueous solution), for example. Examples of the organic solvent include ketones such as acetone, methyl ethyl ketone, methyl i-butyl ketone, cyclopentanone, cyclohexanone, 3-methylcyclopentanone, and 2,6-dimethylcyclohexanone; alcohols such as methanol, ethanol, n-propyl alcohol, i-propyl alcohol, n-butyl alcohol, t-butyl alcohol, cyclopentanol, cyclohexanol, 1,4-hexanediol, and 1,4-hexanedimethylol; ethers such as tetrahydrofuran and dioxane; esters such as ethyl acetate, n-butyl acetate, and i-amyl acetate; aromatic hydrocarbons such as toluene and xylene; phenol, acetonylacetone, dimethylformamide; and the like. These organic solvents may be used either individually or in combination. The organic solvent is preferably used in an amount of 100 parts by volume or less based on 100 parts by volume of the alkaline aqueous solution. If the amount of the organic solvent exceeds 100 parts by volume, the developability may decrease so that the exposed area may remain undeveloped. An appropriate amount of a surfactant or the like may also be added to the developer. The resist film is normally washed with water and dried after development using the developer.

### EXAMPLES

The embodiment of the invention is further described below by way of examples. Note that the invention is not limited to the following examples. The property values were measured by the following methods (1) and (2).

### (1) Weight Average Molecular Weight (Mw) and Number Average Molecular Weight (Mn)

The weight average molecular weight (Mw) and the number average molecular weight (Mn) were measured using GPC columns (manufactured by Tosoh Corp., G2000HXL×2, G3000HXL×1, G4000HXL×1) at a flow rate of 1.0 ml/min and a column temperature of 40° C. (eluant: tetrahydrofuran, standard reference material: monodisperse polystyrene). The dispersibility (Mw/Mn) was calculated from the measurement results.

### (2) Content of Low-Molecular-Weight Components Derived From Monomers

The content of low-molecular-weight components derived from monomers was determined by high-performance liquid chromatography (HPLC) using an Intersil ODS-25 μm column (manufactured by GL Sciences Inc., inner diameter: 4.6 mm, length: 250 mm) (flow rate: 1.0 ml/min, eluant: 0.1% phosphoric acid aqueous solution of acrylonitrile).

### <Synthesis of Polymers (A-1) to (A-13)>

Polymers (A-1) to (A-13) were synthesized using polymerizable monomers shown by the following formulas (M1-1) to (M5-5).

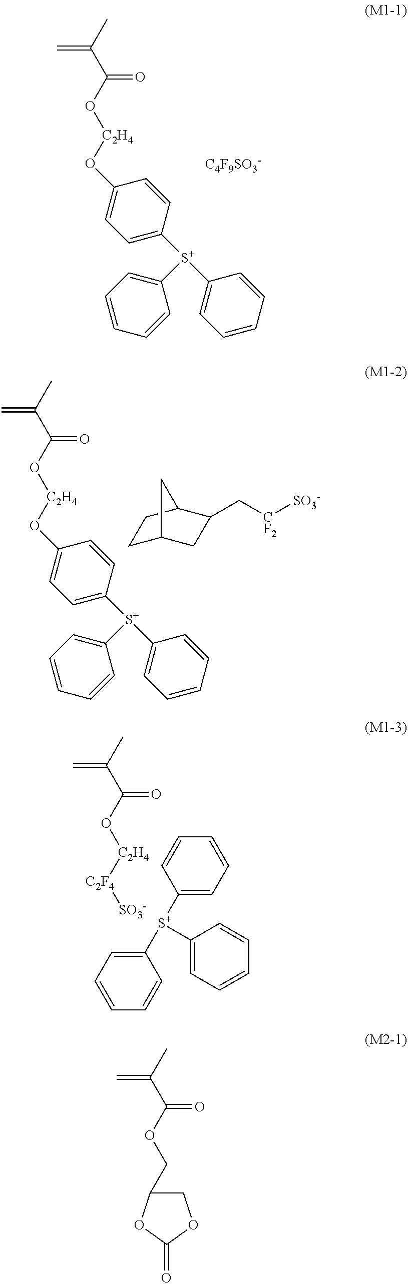

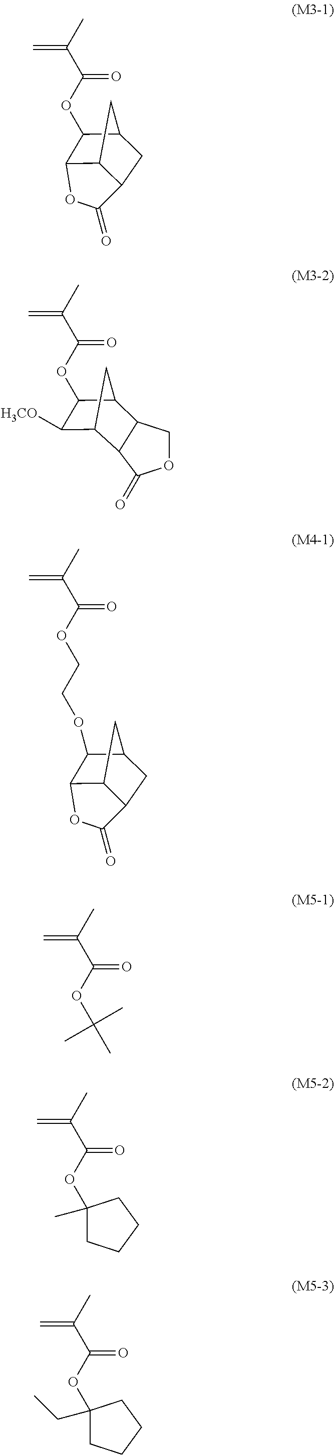

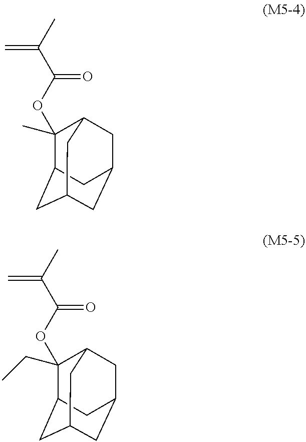

Each polymerizable monomer was dissolved in 60 g of methyl ethyl ketone in a combination and a ratio (mol %) shown in Table 1. An initiator (AIBN) was added to the solution to prepare a monomer solution. The total amount of the monomers was 30 g. The amount of polymerizable monomer is indicated by the ratio (mol %) based on the total amount of the monomers. The initiator was added in an amount of 5 mol % based on the total amount of the monomers and the initiator.

A 500 ml three-necked flask equipped with a thermometer and a dropping funnel was charged with 30 g of a solvent (methyl ethyl ketone), and purged with nitrogen for 30 minutes. The solvent was heated to 80° C. with stiffing using a magnetic stirrer. The monomer solution was added dropwise to the solvent heated at 80° C. over three hours using the dropping funnel. After the addition, the mixture was aged for three hours, and allowed to cool to 30° C. or less to obtain a copolymer solution. The copolymer solution was washed with a methanol solution, and re-precipitated to obtain a polymer ((A-1) to (A-13)). The ratio (mol %) of a repeating unit derived from each polymerizable monomer in the polymers (A-1) to (A-13), and the Mw and Mw/Mn analysis results are shown in Table 1.

TABLE 1

| | Ratio (mol %) of monomers | | | | | | | | | | | | | |
|---|---|---|---|---|---|---|---|---|---|---|---|---|---|---|
| Polymer | used/ratio (mol %) of monomers in polymer (A) | | | | | | | | | | | | | |
| (A) | M1-1 | M1-2 | M1-3 | M2-1 | M3-1 | M3-2 | M4-1 | M5-1 | M5-2 | M5-3 | M5-4 | M5-5 | Mw | Mw/Mn |
| A-1 | — | — | 3 | 20 | 27 | — | — | 15 | 35 | — | — | — | 20267 | 1.44 |
| | | | 3.1 | 19.2 | 26.9 | | | 15.5 | 35.3 | | | | | |
| A-2 | — | — | 3 | 20 | 27 | — | — | — | 35 | — | 15 | — | 21349 | 1.42 |
| | | | 2.9 | 19.3 | 27.3 | | | | 36.0 | | 14.5 | | | |
| A-3 | — | — | 3 | 51 | — | — | — | — | 46 | — | — | — | 18567 | 1.50 |
| | | | 3.2 | 50.5 | | | | | 46.3 | | | | | |
| A-4 | — | — | 3 | 37 | — | — | — | — | 60 | — | — | — | 19387 | 1.44 |
| | | | 3.1 | 36.6 | | | | | 60.3 | | | | | |
| A-5 | — | — | 3 | 57 | — | — | — | — | 40 | — | — | — | 18087 | 1.40 |
| | | | 55.7 | 3.3 | | | | | 41.0 | | | | | |
| A-6 | — | — | 3 | 20 | 27 | — | — | — | — | 35 | — | 15 | 20487 | 1.43 |
| | | | 3.0 | 20.8 | 28.2 | | | | | 33.8 | | 14.2 | | |
| A-7 | — | — | 3 | — | 27 | 20 | — | 15 | 35 | — | — | — | 19890 | 1.42 |
| | | | 3.0 | | 28.1 | 18.8 | | 14.3 | 35.8 | | | | | |
| A-8 | — | — | 3 | — | 27 | — | 20 | 15 | 35 | — | — | — | 17659 | 1.45 |
| | | | 3.0 | | 26.2 | | 20.8 | 14.6 | 35.4 | | | | | |
| A-9 | 3 | | — | 51 | — | — | — | — | 46 | — | — | — | 19620 | 1.47 |
| | 2.9 | | | 52.1 | | | | | 45.0 | | | | | |
| A-10 | — | 3 | — | 20 | 27 | — | — | 15 | 35 | — | — | — | 19540 | 1.50 |
| | | 3.2 | | 19.1 | 26.5 | | | 15.8 | 35.4 | | | | | |
| A-11 | — | — | — | — | 50 | — | — | — | 50 | — | — | — | 8100 | 1.45 |
| | | | | | 51.7 | | | | 48.3 | | | | | |
| A-12 | — | — | — | 10 | 40 | — | — | — | 50 | — | — | — | 6900 | 1.40 |
| | | | | 11.0 | 40.5 | | | | 48.5 | | | | | |
| A-13 | — | — | 3 | — | 47 | — | — | 15 | 35 | — | — | — | 21100 | 1.43 |
| | | | 3.5 | | 48.3 | | | 14.8 | 33.4 | | | | | |

The content of low-molecular-weight components derived from the polymerizable monomers in each polymer was analyzed by HPLC, and found to be 0.05 mass % or less based on 100 mass % of the polymer.

### <Preparation of Radiation-Sensitive Resin Composition>

Radiation-sensitive resin compositions of Examples 1 to 10 were prepared by mixing the polymer (A), the solvent (B), and the nitrogen-containing compound (C) in a ratio shown in Table 2. Radiation-sensitive resin compositions of Comparative Examples 1 to 3 were prepared by mixing the polymer (A), the solvent (B), the nitrogen-containing compound (C), and the additional acid generator (D). The polymers (A-1) to (A-13) shown in Table 2 respectively correspond to the polymers (A-1) to (A-13) shown in Table 1. The following compounds were used as the solvent (B), the nitrogen-containing compound (C), and the additional acid generator (D).

### Solvent (B)

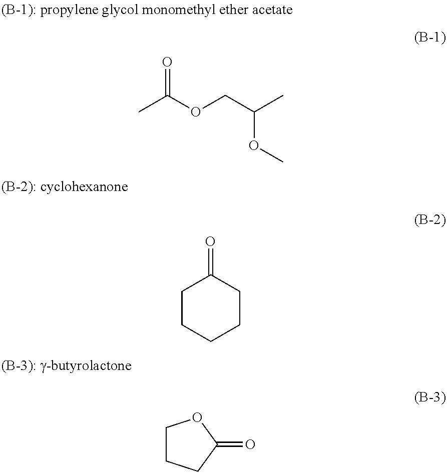

### Nitrogen-Containing Compound (C)

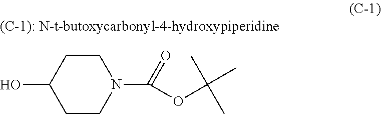

### Acid Generator (D)

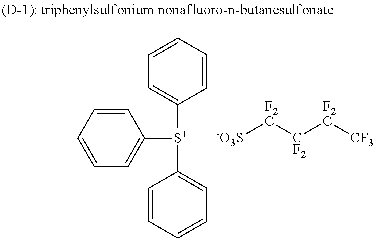

TABLE 2

| | | | | | Nitrogen-containing | Additional acid |
|---|---|---|---|---|---|---|
| | Polymer (A) | Solvent (B) | | | compound (C) | generator (D) |
| | (parts) | (parts) | | | (parts) | (parts) |
| Example 1 | A-1 | B-1 | B-2 | B-3 | C-1 | — |
| | (100) | (1500) | (650) | (30) | (1.1) | |
| Example 2 | A-2 | B-1 | B-2 | B-3 | C-1 | — |
| | (100) | (1500) | (650) | (30) | (1.1) | |
| Example 3 | A-3 | B-1 | B-2 | B-3 | C-1 | — |
| | (100) | (1500) | (650) | (30) | (1.1) | |
| Example 4 | A-4 | B-1 | B-2 | B-3 | C-1 | — |
| | (100) | (1500) | (650) | (30) | (1.1) | |
| Example 5 | A-5 | B-1 | B-2 | B-3 | C-1 | — |
| | (100) | (1500) | (650) | (30) | (1.1) | |
| Example 6 | A-6 | B-1 | B-2 | B-3 | C-1 | — |
| | (100) | (1500) | (650) | (30) | (1.1) | |
| Example 7 | A-7 | B-1 | B-2 | B-3 | C-1 | — |
| | (100) | (1500) | (650) | (30) | (1.1) | |
| Example 8 | A-8 | B-1 | B-2 | B-3 | C-1 | — |
| | (100) | (1500) | (650) | (30) | (1.1) | |
| Example 9 | A-9 | B-1 | B-2 | B-3 | C-1 | — |
| | (100) | (1500) | (650) | (30) | (1.1) | |
| Example 10 | A-10 | B-1 | B-2 | B-3 | C-1 | — |
| | (100) | (1500) | (650) | (30) | (1.1) | |
| Comparative Example 1 | A-11 | B-1 | B-2 | B-3 | C-1 | D-1 |
| | (100) | (1500) | (650) | (30) | (1.1) | (1) |
| Comparative Example 2 | A-12 | B-1 | B-2 | B-3 | C-1 | D-1 |
| | (100) | (1500) | (650) | (30) | (1.1) | (1) |
| Comparative Example 3 | A-13 | B-1 | B-2 | B-3 | C-1 | D-1 |
| | (100) | (1500) | (650) | (30) | (1.1) | (1) |

### <Evaluation of Radiation-Sensitive Resin Composition>

The following items (1) to (3) were evaluated for the radiation-sensitive resin compositions of Examples 1 to 10 and Comparative Examples 1 to 3. The evaluation results are shown in Table 3.

### (1) Sensitivity

An 8-inch silicon wafer on which an underlayer antireflective film (“ARC29A” manufactured by Bruwer Science, thickness: 77 nm) was formed was used as a substrate. The underlayer antireflective film was formed using a system “CLEAN TRACK ACT8” (manufactured by Tokyo Electron Ltd.). The radiation-sensitive resin composition shown in Table 2 was spin-coated onto the substrate using the system “CLEAN TRACK ACT8”, and pre-baked (PB) under conditions shown in Table 3 to form a resist film having a thickness of 100 nm. The resist film was exposed through a mask pattern using an ArF excimer laser exposure system (“NSR S306C” manufactured by Nikon Corp., NA=0.78, sigma=CONVENTIONAL). After performing PEB under the conditions shown in Table 3, the resist pattern was developed at 23° C. for 30 seconds using a 2.38 mass % tetramethylammonium hydroxide aqueous solution, washed with water, and dried to form a positive-tone resist pattern. A dose (mJ/cm²) at which a 1:1 line-and-space pattern having a line width of 150 nmL was formed through a 1:1 line-and-space mask (design dimension: 150 nmL) was determined to be an optimum dose (mJ/cm²). The optimum dose was taken as the sensitivity (mJ/cm²). The pattern dimensions were measured using a scanning electron microscope (“S-9380” manufactured by Hitachi High-Technologies Corporation).

### (2) Isolated Space Depth of Focus (DOF)

A focus amplitude when 90 nmS/1150 nmP pattern dimensions resolved at the optimum dose through a 115 nmS/1150 nmP mask pattern were within the range of 81 to 99 nmS/1150 nmP, was taken as the isolated space depth of focus (μm). The pattern dimensions were measured using the above scanning electron microscope.

### (3) MEEF

The dimensions of a pattern resolved at the optimum dose through each mask (85.0 nmL/180 nmP, 87.5 nmL/180 nmP, 90.0 nmL/180 nmP, 92.5 nmL/180 nmP, 95.0 nmL/180 nmP) were measured. The mask size (horizontal axis) and the line width (vertical axis) were plotted on a graph, and the slope of the graph was determined by the least-square method. The slope was taken as the MEEF. The pattern dimensions were measured using the above scanning electron microscope.

TABLE 3

| | PB | | | | |
|---|---|---|---|---|---|
| | Temperature | PEB | | | |
| | (° C.)/ | Temperature | | DOF | Sensitivity |
| | time (s) | (° C.)/time (s) | MEEF | (μm) | (mJ/cm²) |
| Example 1 | 100° C./60 s | 120° C./60 s | 3.9 | 0.20 | 50 |
| Example 2 | 100° C./60 s | 130° C./60 s | 3.9 | 0.20 | 48 |
| Example 3 | 100° C./60 s | 120° C./60 s | 3.8 | 0.20 | 44 |
| Example 4 | 100° C./60 s | 140° C./60 s | 4.1 | 0.20 | 44 |
| Example 5 | 100° C./60 s | 150° C./60 s | 4.3 | 0.20 | 46 |
| Example 6 | 100° C./60 s | 115° C./60 s | 4.0 | 0.20 | 44 |
| Example 7 | 100° C./60 s | 120° C./60 s | 3.9 | 0.20 | 51 |
| Example 8 | 100° C./60 s | 120° C./60 s | 3.9 | 0.20 | 50 |
| Example 9 | 100° C./60 s | 120° C./60 s | 4.2 | 0.20 | 40 |
| Example 10 | 100° C./60 s | 120° C./60 s | 3.7 | 0.20 | 54 |
| Comparative | 100° C./60 s | 110° C./60 s | 4.4 | 0.13 | 68 |
| Example 1 | | | | | |
| Comparative | 100° C./60 s | 110° C./60 s | 4.4 | 0.15 | 70 |
| Example 2 | | | | | |
| Comparative | 100° C./60 s | 120° C./60 s | 4.0 | 0.13 | 52 |
| Example 3 | | | | | |

As is clear from Table 3, the radiation-sensitive resin compositions according to the examples of the embodiment of the invention exhibited an excellent DOF-MEEF balance and excellent sensitivity as compared with the comparison resins.

The radiation-sensitive resin compositions according to the embodiments of the invention exhibit excellent resolution and an excellent DOF-MEEF balance when forming a fine pattern having a line width of 90 nm or less, and may be suitably used for liquid immersion lithography.

The above radiation-sensitive resin composition according to the embodiments of the present invention exhibits excellent resolution and an excellent DOF-MEEF balance when forming a fine pattern having a line width of 90 nm or less, and may be suitably used for liquid immersion lithography.

The above polymer according to the embodiments of the present invention may be used for a radiation-sensitive resin composition that exhibits excellent resolution and an excellent DOF-MEEF balance when forming a fine pattern having a line width of 90 nm or less, and may be suitably used for liquid immersion lithography.

Obviously, numerous modifications and variations of the invention are possible in light of the above teachings. It is therefore to be understood that within the scope of the appended claims, the invention may be practised otherwise than as specifically described herein.

What is claimed as new and desired to be secured by Letters Patent of the United States is:

1. A radiation-sensitive resin composition comprising:
a solvent; and
a polymer comprising:
a first repeating unit shown by a general formula (1); and
at least one of a second repeating unit shown by a general formula (2), a third repeating unit shown by a general formula (3), and a fourth repeating unit shown by a general formula (4), 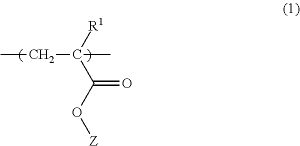
wherein R¹ represents a hydrogen atom, a methyl group, or a trifluoromethyl group, and Z represents a monovalent group that generates an acid upon exposure to radiation, 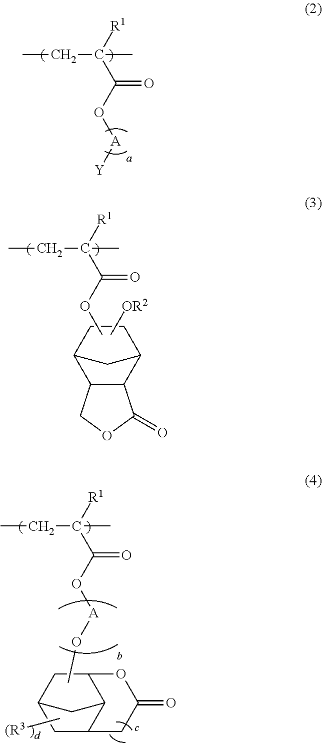
wherein R¹ represents a hydrogen atom, a methyl group, or a trifluoromethyl group, A represents a methylene group, a linear or branched alkylene group having 2 to 10 carbon atoms, or an arylene group having 3 to 10 carbon atoms, Y represents a group that includes a structure shown by a general formula (i), a is 0 or 1, R² represents a linear or branched alkyl group having 1 to 10 carbon atoms, R³ represents a linear or branched alkyl group having 1 to 10 carbon atoms, a halogen atom, or a cyano group, b is an integer from 2 to 4, c is 0 or 1, and d is an integer from 0 to 2, 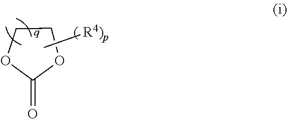
wherein R⁴ represents a hydrogen atom or a linear or branched alkyl group having 1 to 5 carbon atoms, p is 1 or 2, q is 1 or 2, and two R⁴ is same or different when p is 2.

2. The radiation-sensitive resin composition according to claim 1, wherein the repeating unit (1) comprises at least one of a repeating unit (1-1) shown by a following general formula (1-1) and a repeating unit (1-2) shown by a following general formula (1-2), 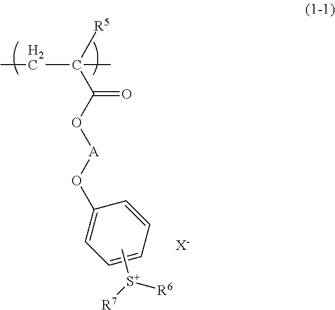
wherein R⁵ represents a hydrogen atom, a methyl group, or a trifluoromethyl group, R⁶ and R⁷ represent a substituted or unsubstituted linear or branched alkyl group having 1 to 10 carbon atoms, a substituted or unsubstituted linear or branched alkoxy group having 1 to 10 carbon atoms, or a substituted or unsubstituted aryl group having 3 to 10 carbon atoms, A represents a methylene group, a linear or branched alkylene group having 2 to 10 carbon atoms, or an arylene group having 3 to 10 carbon atoms, and X⁻ represents a counter anion of a sulfonium ion. 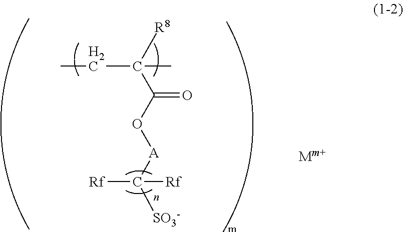
wherein R⁸ represents a hydrogen atom, a methyl group, or a trifluoromethyl group, Rf represents a fluorine atom or a linear or branched perfluoroalkyl group having 1 to 10 carbon atoms, A represents a methylene group, a linear or branched alkylene group having 2 to 10 carbon atoms, or an arylene group having 3 to 10 carbon atoms, M^{m+} represents an onium cation, m is an integer from 1 to 3, and n is an integer from 1 to 8.

3. The radiation-sensitive resin composition according to claim 1, wherein the polymer further comprises a repeating unit (5) shown by a following general formula (5), 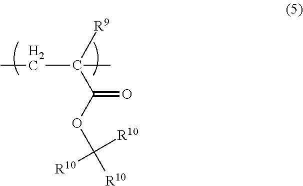
wherein R⁹ represents a hydrogen atom, a methyl group, or a trifluoromethyl group, and R¹⁰ represents a monovalent alicyclic hydrocarbon group having 4 to 20 carbon atoms, a derivative of the monovalent alicyclic hydrocarbon group, or a linear or branched alkyl group having 1 to 4 carbon atoms, and two of R¹⁰ bond to form an alicyclic hydrocarbon group having 4 to 20 carbon atoms or a derivative of the alicyclic hydrocarbon group.

4. The radiation-sensitive resin composition according to claim 1, further comprising a nitrogen-containing compound.

5. The radiation-sensitive resin composition according to claim 1, further comprising a photoacid generator which is other than the polymer.

6. A polymer comprising:
a first repeating unit (1) shown by a general formula (1); and
at least one of a second repeating unit shown by a general formula (2), a third repeating unit shown by a general formula (3), and a fourth repeating unit shown by a general formula (4), 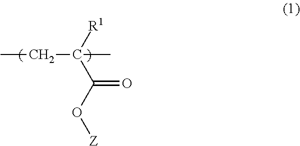
wherein R¹ represents a hydrogen atom, a methyl group, or a trifluoromethyl group, and Z represents a monovalent group that generates an acid upon exposure to radiation, 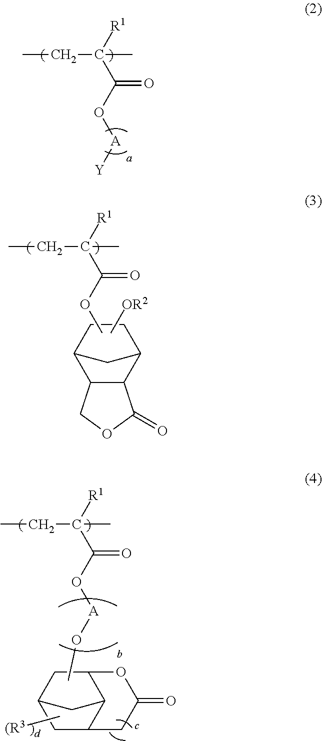
wherein R¹ represents a hydrogen atom, a methyl group, or a trifluoromethyl group, A represents a methylene group, a linear or branched alkylene group having 2 to 10 carbon atoms, or an arylene group having 3 to 10 carbon atoms, Y represents a group that includes a structure shown by a general formula (i), a is 0 or 1, R² represents a linear or branched alkyl group having 1 to 10 carbon atoms, R³ represents a linear or branched alkyl group having 1 to 10 carbon atoms, a halogen atom, or a cyano group, b is an integer from 2 to 4, c is 0 or 1, and d is an integer from 0 to 2, 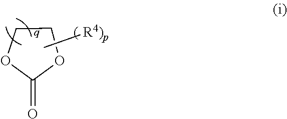
wherein R⁴ represents a hydrogen atom or a linear or branched alkyl group having 1 to 5 carbon atoms, p is 1 or 2, and q is 1 or 2, and two R⁴ is same or different when p is 2.
